(19) United States
(12) Patent Application Publication
(10) Pub. No.: US 2004/0089470 A1
(43) Pub. Date: May 13, 2004

(54) Printed circuit board, semiconductor package, base insulating film, and manufacturing method for interconnect substrate

(75) Inventors: Tadanori Shimoto, Tokyo (JP); Hirokazu Honda, Tokyo (JP); Keiichiro Kata, Tokyo (JP); Hideya Murai, Tokyo (JP); Katsumi Kikuchi, Tokyo (JP); Kazuhiro Baba, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 10/701,594

(22) Filed: Nov. 6, 2003

(30) Foreign Application Priority Data
Nov. 12, 2002 (JP) 328704/2002

(51) Int. Cl. H05K 1/00

(52) U.S. Cl. 174/250

(57) ABSTRACT

A printed circuit board is provided including a lower interconnect, a base insulating film formed on the lower interconnect, and a via hole formed on the base insulating film, and an upper interconnect connected to the lower interconnect with the via hole. The base insulating film has a thickness of about 3 to 100 μm and has a breaking strength of about 80 MPa or more at a temperature of 23° C. and when the base insulating film is defined to have a breaking strength “a” at a temperature of −65° C. and a breaking strength “b” at a temperature of 150° C., a value of a ratio (a/b) is about 4.5 or less.

### BACKGROUND OF THE INVENTION

1. Field of the Invention

The present invention relates to a printed circuit board used in a semiconductor package and module, a semiconductor package using a interconnect substrate, a base insulating film used in the interconnect substrate, and a manufacturing method for the interconnect substrate, and in particular, to a printed circuit board on which various devices such as semiconductor devices can be densely mounted.

2. Description of The Related Art

Recently, the improved performance of semiconductor devices and the provision of multiple functions have led to the increased number of terminals, a reduced pitch, and an increased processing speed. Accordingly, it has been desirable that a mounting printed circuit board on which semiconductor devices are mounted be provided with denser and finer interconnects and operate at a higher speed. An example of a common mounting printed circuit board is a built-up printed circuit board, which is a type of multilayer interconnect substrate.

FIG. 1 is a sectional view showing a conventional built-up printed circuit board. As shown in FIG. 1, this conventional built-up printed circuit board is provided with a base core substrate 73 composed of glass epoxy. A penetrating through-hole 71 of diameter about 300 μm is formed in the base core substrate 73 using a drill. Conductor interconnects 72 are formed on the respective surfaces of the base core substrate 73. Interlayer insulating films 75 are provided so as to cover the respective conductor interconnect 72. A via hole 74 is formed in each interlayer insulating film 75 so as to be connected to the corresponding conductor interconnect 72. A conductor interconnect 76 is provided on a surface of each interlayer insulating film 75 so as to be connected to the corresponding conductor interconnect 72 via the corresponding via hole 74. A multilayer printed circuit board may be obtained as required by repeatedly providing, on the conductor interconnect 76, an interlayer insulating film formed with a via hole as well as a conductor interconnect.

However, in this built-up printed circuit board , the base core substrate 73 is composed of a glass epoxy printed circuit board and thus insufficiently resists heat. Thermal treatment used to form the interlayer insulating film 75 may deform the base core substrate 73, i.e. the base core substrate may undergo contraction, warp, distortion, or the like. As a result, during a step of exposing resist in patterning a conductor layer (not shown) to form the conductor interconnect 76, the positional accuracy of exposure decreases significantly. It is thus difficult to form a dense and fine interconnect pattern on the interlayer insulating film 75. Further, a land portion must be provided in the connection between the conductor interconnect 72 and the penetrating through-hole 71 in order to ensure that the penetrating through-hole 71 and the conductor interconnect 72 are connected together. Even if an interconnect design accommodating an increased operating speed is used for a built-up layer composed of the interlayer insulating film 75 and the conductor interconnect 76, the presence of the land portion makes it difficult to control impedance. Further, loop inductance increases. Thus, disadvantageously, the operating speed of the whole built-up printed circuit board decreases to make it difficult to accommodate an increased speed.

To solve such problems attributed to the penetrating through-holes in the built-up printed circuit board, a printed circuit board method has been proposed which may replace the method of forming penetrating through-holes in a glass epoxy substrate using a drill, for example, in Japanese published patent application 2000-269647 and Drafts for 11-th Microelectronics Symposium, pp.131 to 134.

FIGS. 2(a) to 2(c) are sectional views showing this conventional printed circuit board forming method in order of its steps. First, as shown in FIG. 2(a), prepreg 82 is provided which has predetermined conductor interconnects 81 formed on its surface. Then, through-holes 83 of diameter 150 to 200 μm are formed in the prepreg 82 by laser beam machining. Then, as shown in FIG. 2(b), a conductor paste 84 is buried in each through-hole 83. Then, as shown in FIG. 2(c), a plurality of such prepregs 82, i.e. a plurality of prepregs 82 each formed with the through-holes 83 in which the respective conductor pastes 84 are buried, are produced and stacked. At this time, a land pattern 86 in each conductor interconnect 81 is connected to the corresponding through-hole 83 in the adjacent prepreg. This enables the production of a printed circuit board 85 without any penetrating through-holes.

However, with this conventional technique, the positional accuracy with which the prepregs 82 are stacked is low. Further, it is difficult to reduce the diameter of the land pattern 86. This makes it difficult to provide dense interconnects. Furthermore, this technique is not sufficiently effective in improving the controllability of impedance or reducing loop inductance. Moreover, the connections of the through-holes established after the stacking are not reliable.

To solve the above described large number of problems, Japanese published patent application 2002-198462 disclosed a method of producing a printed circuit board by forming an interconnect layer on a support such as a metal plate and subsequently removing the support. FIGS. 3(a) and 3(b) are sectional views showing this conventional printed circuit board manufacturing method. First, as shown in FIG. 3(a), a support plate 91 composed of a metal plate or the like is provided. Then, conductor interconnects 92 are formed on the support plate 91. An interlayer insulating film 93 is then formed so as to cover the conductor interconnects 92. Via holes 94 are then formed in the interlayer insulating film 93 so as to be connected to the respective conductor interconnects 92. Subsequently, conductor interconnects 95 are formed on the interlayer insulating film 93. The conductor interconnects 95 are formed so as to be connected to the respective conductor interconnects 92 via the respective via holes 94. A multilayer printed circuit board may be obtained as required by repeating the steps of forming the interlayer insulating film 93, the via holes 94, and the conductor interconnects 95. Then, as shown in FIG. 3(b), the support plate 91, is partly removed by etching to expose the conductor interconnects 92, while forming supports 96. Thus, a printed circuit board 97 is manufactured.

In this case, the interlayer insulating film 93 is composed of a single layer film consisting of an insulating material having a film strength of 70 MPa or more, a breaking elongation percentage of 5% or more, a glass transition temperature of 150° C. or more, and a coefficient of thermal expansion of 60 ppm or less or a single layer film consisting of an insulating material having an elastic modulus of 10 GPa or more, a coefficient of thermal expansion of 30 ppm or less, and a glass transition temperature of 150° C. or more.

According to this technique, no penetrating through-holes are present in the printed circuit board 97. This serves to solve the previously described problems attributed to the penetrating through-holes. Consequently, interconnects accommodating high operating speeds can be designed. Further, since the support plate 91 is made of a metal plate or the like, which sufficiently resists heat, the substrate is not deformed, i.e. it does not undergo contraction, warp, distortion, or the like as in the case with the glass epoxy substrate. Therefore, dense and fine interconnects can be provided. Furthermore, by defining the mechanical properties of the interlayer insulating film 93 as described above, a strong printed circuit board can be obtained.

However, the above described conventional technique has the problems shown below. Owing to the absence of a base core substrate, the printed circuit board 97 shown in FIG. 3(b) is very thin. However, the printed circuit board 97 is sufficiently strong immediately after manufacturing because the mechanical properties of the interlayer insulating film 93 are defined as described above. However, a semiconductor device that is large in area is mounted on the printed circuit board 97 to form a semiconductor package. The semiconductor package is mounted on a mounting board such as a printed circuit board. The semiconductor device generates heat to increase its temperature while in operation but stops generating heat to reduce its temperature while out of operation. Thus, while the semiconductor device is in operation, the printed circuit board 97 is thermally stressed because of a difference in coefficient of thermal expansion between the semiconductor device and the mounting board. Consequently, when the semiconductor device mounted on the printed circuit board 97 as described previously is repeatedly operated, the printed circuit board 97 is repeatedly thermally stressed. Therefore, the interlayer insulating film 93 or the like in the printed circuit board 97 may be cracked. This makes it impossible to provide the printed circuit board and semiconductor package with required reliability.

### SUMMARY OF THE INVENTION

The present invention provides a reliable printed circuit board on which various devices such as semiconductor devices can be densely mounted and a semiconductor package using this printed circuit board and a manufacturing method for the interconnect substrate.

According to a first embodiment of the present invention, a printed circuit board comprises a lower interconnect, a base insulating film formed on the lower interconnect, a via hole formed on the base insulating film, and an upper interconnect connected to the lower interconnect with the via hole, wherein the base insulating film has a thickness of about 3 to 100 μm and has a breaking strength of about 80 MPa or more at a temperature of 23° C., and wherein when the base insulating film is defined to have a breaking strength “a” at a temperature of −65° C. and a breaking strength “b” at a temperature of 150° C., a value of a ratio (a/b) is about 4.5 or less.

According to a second embodiment of the present invention, a manufacturing method for a printed circuit board comprises, providing a support substrate, forming a lower interconnect on a support substrate, forming a base insulating film having a thickness of 3 to 100 μm, forming a via hole in a part of a base insulating film, forming an upper interconnect on the base insulating film so that the upper interconnect is connected to the lower interconnect via the via hole, and removing the support substrate, wherein the step of forming the base insulating film includes a step of coating an insulating material on the support substrate, the insulating material having a breaking strength of about 80 MPa or more at a temperature of 23° C., and when the insulating material is defined to have a breaking strength “a” at a temperature of −65° C. and a breaking strength “b” at a temperature of 150° C., a value of a ratio (a/b) is about 4.5 or less.

### BRIEF DESCRIPTION OF THE DRAWINGS

FIG. 1 is a sectional view showing a conventional built-up printed circuit board.

FIGS. 2(a) to 2(c) are sectional views showing a forming method for this conventional printed circuit board in order of steps of the method.

FIGS. 3(a) and 3(b) are sectional views showing a manufacturing method for another conventional printed circuit board in order of steps of the method.

FIG. 4 is a sectional view of a printed circuit board according to a first embodiment of the present invention.

FIG. 5 is a sectional view showing a semiconductor package according to the first embodiment.

FIG. 6 is a graph showing stress-distortion curves for a base insulating film.

FIG. 7 is a sectional view showing a semiconductor package according to a variation of the first embodiment.

FIG. 8 is a sectional view showing a printed circuit board according to a second embodiment of the present invention.

FIG. 9 is a sectional view showing a manufacturing method for a printed circuit board according to a variation of the second embodiment.

FIG. 10 is a sectional view showing a printed circuit board according to a third embodiment of the present invention.

FIG. 11 is a sectional view showing a semiconductor package according to the third embodiment.

FIG. 12 is a sectional view showing a printed circuit board according to a fourth embodiment of the present invention.

FIG. 13 is a sectional view showing a semiconductor package according to the fourth embodiment.

FIGS. 14(a) to 14(c) are sectional views showing a manufacturing method for a printed circuit board according to a fifth embodiment of the present invention.

FIG. 15 is a sectional view showing a printed circuit board according to a sixth embodiment of the present invention.

FIGS. 16(a) to 16(e) are sectional views showing a manufacturing method for the printed circuit board according to the sixth embodiment in order of steps of the method.

FIGS. 17(a) and 17(b) are sectional views showing a manufacturing method for the semiconductor package according to the first embodiment in order of steps of the method, and FIG. 17(c) is a sectional view showing the semiconductor package provided with a molding.

FIG. 18 is a sectional view showing a manufacturing method for the printed circuit board according to the second embodiment.

FIGS. 19(a) to 19(d) are sectional views showing a manufacturing method for the printed circuit board according to the third embodiment.

FIGS. 20(a) to 20(d) are sectional views showing a manufacturing method for the printed circuit board according to the fourth embodiment in order of steps of the method.

FIG. 21(a) is a photograph showing a shape of CSP (Chip Sized Package) sample for evaluative tests, and FIG. 21(b) is a photograph showing a shape of an FCBGA (Flip Chip Ball Grid Array) sample (optical photomicrographs) for evaluative tests.

FIG. 22 is a photograph substituted for a drawing and showing that in an FCBGA sample in Example No. 5 of the present invention, the development of a crack is stopped in an insulating layer (optical photomicrograph).

FIGS. 23(a) to 23(c) are photographs showing the FCBGA sample in Example No. 5 of the present invention.

FIGS. 24(a) and 24(b) are photographs showing defective parts of open samples for a crack in a resin and for a crack in a solder ball, respectively.

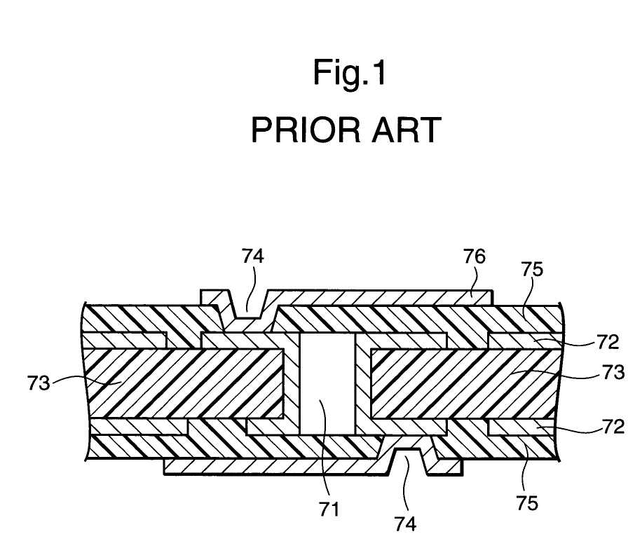

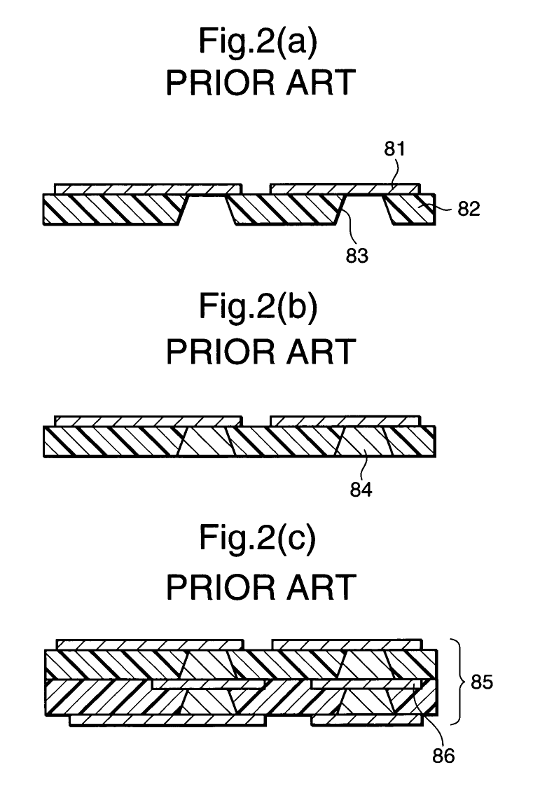

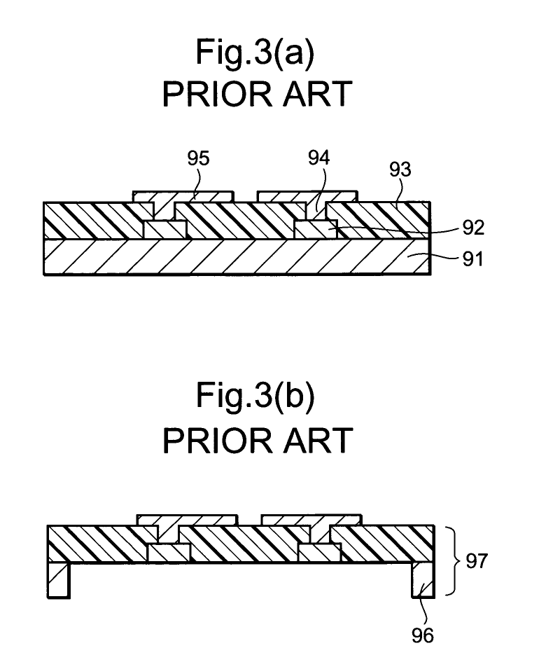

### DETAILED DESCRIPTION OF THE INVENTION

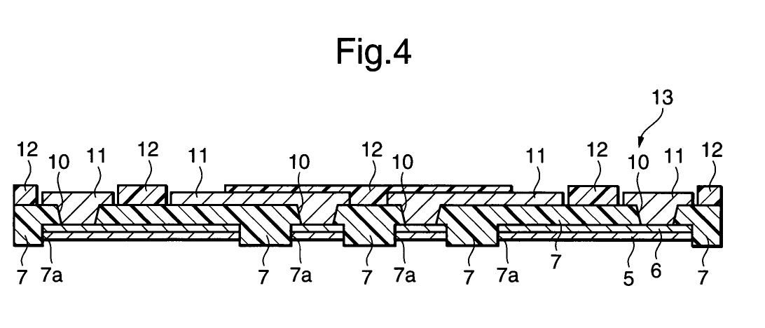

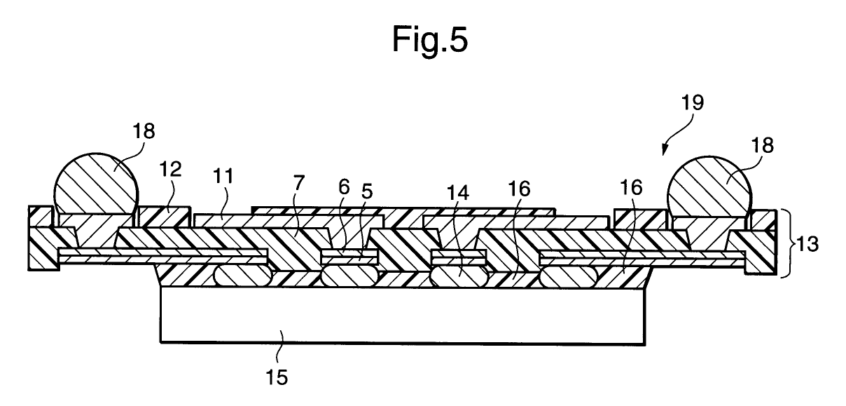

Embodiments of the present invention will be specifically described below with reference to the drawings. First, a first embodiment of the present invention will be described. FIG. 4 is a sectional view showing a printed circuit board according to the present embodiment. FIG. 5 is a sectional view showing a semiconductor package according to the present embodiment.

As shown in FIG. 4, a base insulating film 7 is provided in a printed circuit board 13 according to the present embodiment. The base insulating film 7 has a thickness of 3 to 100 μm, has a breaking strength of 80 MPa or more at a temperature of 23° C., and has an elastic modulus of 2.3 GPa or more at a temperature of 150° C. Further, when the base insulating film 7 is defined to have a breaking strength “a” (MPa) at a temperature of −65° C. and a breaking strength “b” (MPa) at a temperature of 150° C., the value of the ratio (a/b) is 4.5 or less, or 2.5 or less. When the base insulating film is defined to have an elastic modulus “c” (GPa) at a temperature of −65° C. and an elastic modulus “d” (GPa) at a temperature of 150° C., for the breaking strengths “a” and “b” and the elastic module “c” and “d”, the value of the ratio (c/d) is 4.7 or less. Further, the items “a” to “d” satisfy a Formula.

$$\vert \frac{c}{d} - \frac{a}{b} \vert \leq 0.8 \qquad Formula 1$$

Further, a first illustrative embodiment of the value of the ratio (a/b) is 0.22 or more, and particularly a second illustrative embodiment of the value of the ratio (a/b) is 1.0 or more. In addition, a first illustrative embodiment of the value of ratio (c/d) is 0.21 or more, and particularly a second illustrative embodiment of the value of ratio (c/d) is 1.0 or more.

The base insulating film 7 is a resin such as polyimide and a liquid crystal polymer that strongly resists heat and has a high film strength. This resin may be AP-6832C manufactured by NITTO DENKO CORPORATION, UPILEX-S or UPILEX-RN manufactured by UBE INDUSTRIES LTD., KAPTON-H, KAPTON-V, or KAPTON-EN manufactured by DU PONT-TORAY CO., LTD. or Vexter manufactured by KURARAY CO., LTD. Alternatively, the resin may be a fibrous material such as a glass cloth or aramid fibers which has a high strength, a large elastic modulus, and a small dielectric constant and which is impregnated with a resin, for example, a glass cloth impregnated with an epoxy resin such as ABF-GX-1031 manufactured by Ajinomoto Fine-Techno Co., Inc. or an aramid non-woven cloth material such as EA-541 manufactured by Shin-Kobe Electric Machinery Co., Ltd.

Concave portions 7a are formed in the bottom surface of the base insulating film 7. An interconnect main body 6 is formed in each concave portion 7a. An etching barrier layer 5 is formed under the interconnect main body 6. The etching barrier layer 5 and the interconnect main body 6 form a lower interconnect. The lower interconnect is buried in each concave portion 7a. The bottom surface of the etching barrier layer 5 is exposed to constitute a part of the bottom surface of the printed circuit board 13. The interconnect main body 6 is formed of, for example, Cu, Ni, Au, Al, or Pd and has a film thickness of, for example, 2 to 20 μm. The etching barrier layer 5 is formed of, for example, Ni, Au, or Pd and has a film thickness of, for example, 0.1 to 7.0 μm. The bottom surface of the etching barrier layer 5 is located, for example, 0.5 to 10 μm above the bottom surface of the base insulating film 7, i.e. at a deep position in the concave portion 7a.

Further, a via hole 10 is formed in a part of that area of the base insulating film 7 which is located immediately above each concave portion 7a. If the printed circuit board 13 is used for a semiconductor package composed of a CSP (Chip Sized Package), the via hole 10 is, for example, 40 μm in diameter. If the printed circuit board 13 is used for a semiconductor package composed of an FCBGA (Flip Chip Ball Grid Array), the via hole 10 is, for example, 75 μm in diameter. Furthermore, a conductive material is buried in the via hole 10. Upper interconnects 11 are formed on the base insulating film 7. The conductive material in each via hole 10 is integrated with the corresponding upper interconnect 11. The upper interconnect 11 has a film thickness of, for example, 2 to 20 μm and is connected to a lower interconnect via the corresponding via hole 10. Furthermore, solder resists 12 are each formed on the base insulating film 7 so as to expose a part of the corresponding upper interconnect 11 while covering the remaining part. The solder resist 12 is, for example, 5 to 40 μm in thickness. The exposed part of the upper interconnect 11 constitutes a pad electrode.

FIG. 5 shows a configuration of a semiconductor package according to the present embodiment. As shown in FIG. 5, in a semiconductor package 19 according to the present embodiment, a plurality of bumps 14 are connected to the etching barrier layer 5 in the previously described printed circuit board 13. A semiconductor device 15 is provided under the printed circuit board 13. Electrodes (not shown) of the semiconductor device 15 are connected to the bumps 14. The semiconductor device 15 is, for example, an LSI (Large Scale Integrated circuit). Further, an underfill 16 is filled between the printed circuit board 13 and the semiconductor device 15 around each bump 14. On the other hand, a solder ball 18 is mounted on a part of the exposed portion, i.e. the pad electrode of each upper interconnect 11 in the printed circuit board 13. The solder ball 18 is connected to the corresponding electrode of the semiconductor device 15 via the upper interconnect 11, the via hole 10 (in FIG. 5), the lower interconnect composed of the interconnect main body 6 and etching barrier layer 5, and the bump 14. The semiconductor package 19 is mounted in a mounting board (not shown) via the solder balls 18.

Description will be given below of the base insulating film. When the thickness of the base insulating film is less than 3 μm, the mechanical properties for the printed circuit board may not be obtained. On the other hand, when the thickness of the base insulating film exceeds 100 μm, the workability of the via holes based on laser beam machining is significantly degraded. Therefore, the thickness of the base insulating film may be 3 to 100 μm.

In addition, when the breaking strength of the base insulating film is less than 80 MPa, the mechanical properties for the printed circuit board cannot be obtained. Therefore, the breaking strength of the base insulating film may be 80 MPa or more at a temperature of 23° C.

Further, if the value of the ratio (a/b) exceeds 4.5, the breaking strength decreases markedly when the temperature of the base insulating film rises up to a high temperature (150° C.). Thus, even if the base insulating film has a sufficient strength at a low temperature (−65° C.) and at room temperature (23° C.), the strength varies significantly between the low temperature and the high temperature. Then, the base insulating film cannot endure thermal stress repeatedly applied from the mounted semiconductor device. Consequently, the base insulating film is likely to be cracked. Therefore, the value of the ratio (a/b) should be 4.5 or less, more preferably 2.5 or less.

Further, the first illustrative embodiment of the value of the ratio (a/b) is 0.22 or more. When the breaking strength “a” at a temperature of −65° C. is smaller than the breaking strength “b” at a temperature of 150° C., a reciprocal (b/a) of the value of the ratio (a/b) is used. The maximum number of the value of the ratio (a/b) is 4.5, as mentioned above, then the reciprocal of 4.5 is 0.22. Therefore, if the value of the ratio (a/b) is 0.22 or more, the thermal stress can be endured appropriately. Further, the second illustrative embodiment of the value of the ratio (a/b) is 1.0 or more. When the breaking strength “a” at a temperature of −65° C. and the breaking strength “b” at a temperature of 150° C. is the same, the value of the ratio (a/b) is 1.0. That is, the breaking strength is constant regardless of the change of temperature. Therefore, the reliability for the thermal stress can be increased.

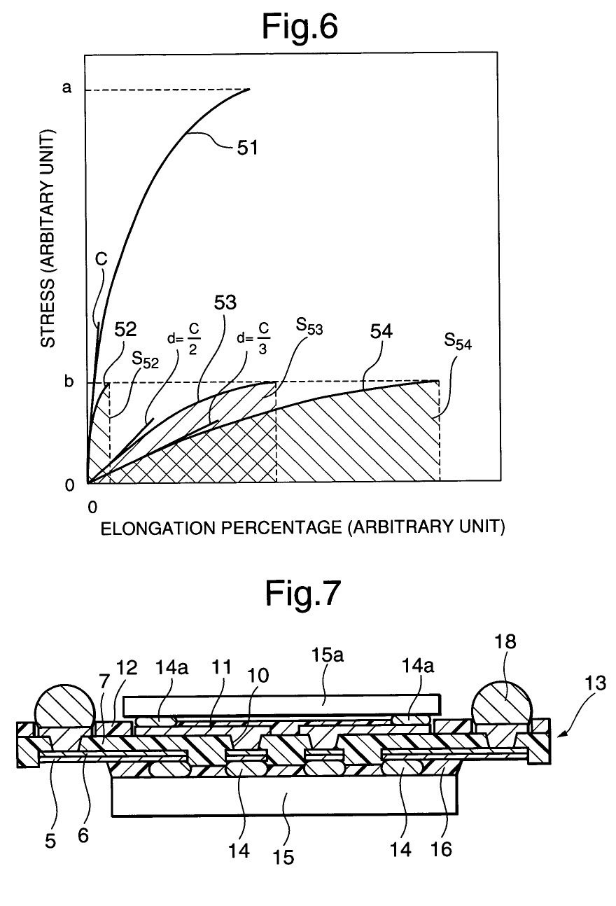

FIG. 6 is a graph showing stress-distortion curves of the base insulating film. In this graph, the axis of abscissa indicates the elongation percentage of the base insulating film, while the axis of ordinate indicates stress applied to the base insulating film. A line 51 shown in FIG. 6 indicates a stress-distortion curve of the base insulating film at a temperature of −65° C. For this curve, the breaking strength is shown by a. Further, the inclination of a part of the line 51 which shows a zero elongation percentage and a zero stress indicates an elastic modulus. Its value is shown by c. The lines 52 to 54 shown in FIG. 6 indicate stress-distortion curves of the base insulating film at a temperature of 150° C. For all these curves, the breaking strength is shown by b. The line 52 indicates that the elastic modulus d at a temperature of 150° C. equals c. The line 53 indicates that the elastic modulus d at a temperature of 150° C. equals (c/2). The line 54 indicates that the elastic modulus d at a temperature of 150° C. equals (c/3).

When the value of the ratio (a/b) is 2.5 or less and the temperature is 150° C., provided that the base insulating film has a sufficient breaking strength, the base insulating film is unlikely to be cracked even if it is repeatedly thermally stressed. Accordingly, the printed circuit board is reliable. However, if the value of the ratio (a/b) is larger than 2.5, the occurrence of cracks in the base insulating film depends on the integral value of the stress-distortion curve. This integral value indicates work done on the base insulating film per unit area before the base insulating film is cracked, and corresponds to the proof stress of the base insulating film. Accordingly, the larger the integral value is, the base insulating film is unlikely to be cracked and highly resistant to cracks. If the integral values of the lines 52 to 54 are defined as S₅₂, S₅₃, and S₅₄, then as shown in FIG. 6, the integral value of the stress-distortion curve increases consistently with the value of the ratio (c/d), or with the reduced elastic modulus d, that is, S₅₂<S₅₃<S₅₄. Thus, in connection with the occurrence of cracks, it is better the value of the ratio (c/d) is large. Exemplary, (c/d)≧(a/b)−0.8 may be applicable.

However, if the value of the ratio (c/d) is too large, the rigidity of the base insulating film may be low at high temperature. Accordingly, the base insulating film is excessively deformed when thermally stressed. As a result, although the base insulating film is not cracked, the solder balls attached to the printed circuit board may not follow the deformation of the base insulating film and may be damaged. Consequently, in an illustrative embodiment, the value of the ratio (c/d) is approximately 4.7 or less, or wherein (c/d)≦(a/b)+0.8. When the absolute value of a difference between the value of the ratio (c/d) and the value of the ratio (a/b) is larger than 0.8, the base insulating film is likely to be cracked or the solder balls are likely to be damaged. Therefore, in an illustrative embodiment, the absolute value of a difference between the value of the ratio (c/d) and the value of the ratio (a/b) is approximately 0.8 or less.

Further, the first illustrative embodiment of the value of ratio (c/d) is 0.21 or more. When the base insulating film is defined to have the elastic modulus “c” at a temperature of −65° C. is smaller than the elastic modulus “d” at a temperature of 150° C., a reciprocal (d/c) of the value of the ratio (c/d) is used. The maximum number of the value of the ratio (c/d) is about 4.7, as mentioned above, then the reciprocal of 4.5 is 0.21. Therefore, if the value of the ratio (c/d) is 0.21 or more, the thermal stress can be endured appropriately. Further, the second illustrative embodiment of the value of ratio (c/d) is 1.0 or more. When the base insulating film is defined to have the elastic modulus “c” at a temperature of −65° C. and the elastic modulus “d” at a temperature of 150° C. is the same, the value of the ratio (c/d) is 1.0. That is, the elastic modulus is constant regardless of the change of temperature. Therefore the reliability for the thermal stress can be increased.

With an elastic modulus of 2.3 GPa or more, the rigidity of the base insulating film is ensured at high temperature. Further, the base insulating film can be prevented from being excessively deformed when stressed. Consequently, the solder balls attached to the printed circuit board can be prevented from being damaged. Therefore, the base insulating film may be an elastic modulus of 2.3 GPa or more at a temperature of 150° C.

When the distance between the bottom surface of the lower interconnect and the bottom surface of the base insulating film is less than 0.5 μm, the effect of preventing the misalignment of the bumps cannot be sufficiently produced. On the other hand, if this distance exceeds 10 μm, when the semiconductor device is mounted on the interconnect substrate, there is only a small gap between the base insulating film and the semiconductor device. Thus, if an underfill is provided by filling an underfill resin into the gap after the semiconductor device has been mounted, it is difficult to pour the underfill resin into the gap. Therefore, this distance may be 0.5 to 10 μm.

In FIG. 5, the semiconductor package 19 according to the present embodiment, the semiconductor device 15 is driven by supplying power from the mounting board (not shown) to the semiconductor device 15 and transmitting signals between the mounting board and the semiconductor device 15, via the solder ball 18, the upper interconnect 11, the via hole 10, the lower interconnect composed of the interconnect main body 6 and etching barrier layer 5, and the bump 14. At this time, the semiconductor device 15 generates heat which is transferred to the mounting board via the printed circuit board 13. At this time, on the basis of a difference in the coefficient of thermal expansion between the semiconductor device 15 and the mounting board, the bump 14, the printed circuit board 13, and the solder ball 18 are thermally stressed. Then, as the semiconductor device 15 repeats its active and inactive states, the bump 14, the printed circuit board 13, and the solder ball 18 are repeatedly thermally stressed.

In the present embodiment, the base insulating film 7 has a thickness of 3 to 100 μm and has a breaking strength of 80 MPa or more at a temperature of 23° C. Accordingly, the strength of the printed circuit board 13 can be obtained. Further, since the value of the ratio (a/b) is 4.5 or less, the breaking strength can be obtained at high temperature. Furthermore, the breaking strengths a and b and the elastic moduli c and d satisfy Formula 1. Accordingly, both base insulating film 7 and solder balls 18 are unlikely to be cracked. Thus, even if the printed circuit board 13 is repeatedly thermally stressed as the semiconductor device 15 repeats its active and inactive states, the base insulating film 7 and the solder balls 18 are not cracked. Therefore, the printed circuit board 13 and the semiconductor package 19 are reliable.

Further, the lower interconnect composed of the etching barrier layer 5 and interconnect main body 6 is present inside each concave portion 7a. Furthermore, the bottom surface of the lower interconnect is located 0.5 to 10 μm above the bottom surface of the base insulating film 7. This prevents the bumps 14 from being misaligned or caused to flow when joined to the semiconductor device. Thus, the bumps 14 can be more reliably connected to the semiconductor device and disposed at fine pitches. Therefore, a highly integrated semiconductor device 15 can be mounted.

Furthermore, no penetrating through-holes are formed in the printed circuit board 13. This avoids the problems attributed to the penetrating through-holes, i.e. difficulties in controlling impedance and an increase in loop inductance. It is thus possible to design highly integrated fine interconnects accommodating high operating speeds.

In the present embodiment, the underfill 16 may be omitted. Further, a flip chip type semiconductor package does not require any moldings, so that the present embodiment does not involve any moldings. However, if the semiconductor package is desired to resist humidity strongly and the sealability (air tightness) of the semiconductor device is to be improved and if the mechanical properties of the semiconductor package are to be improved by compensating for the thinness of the interconnect substrate, a molding may be provided on the bottom surface of the printed circuit board 13 so as to cover the underfill 16 and the semiconductor device 15.

FIG. 7 is a sectional view showing a semiconductor package according to a variation of the present embodiment. As shown in FIG. 7, in the semiconductor package according to the present variation, semiconductor devices are mounted on the respective surfaces of the printed circuit board 13. Specifically, in addition to the semiconductor device 15 connected to the lower interconnect via the bumps 14, a semiconductor device 15a is provided which is connected to the upper interconnect 11 via bumps 14a. Some of the electrodes of the semiconductor device 15 are connected to electrodes (not shown) of the semiconductor device 15a via the bumps 14, the lower interconnect composed of the etching barrier layer 5 and interconnect main body 6, the via holes 10, the upper interconnects 11, and the bumps 14a. The other arrangements of the present variation are similar to those of the previously described first embodiment. Thus, in the present variation, two semiconductor devices can be mounted on the single printed circuit board 13.

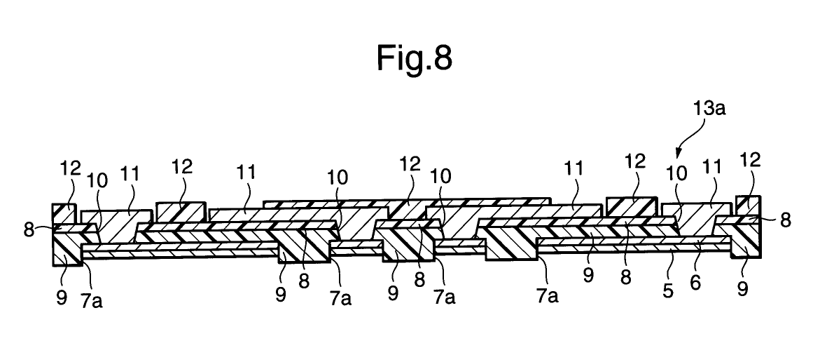

FIG. 8 is a sectional view showing a printed circuit board according to the second embodiment of the present embodiment. As shown in FIG. 8, in a printed circuit board 13a according to the present embodiment, a two-layer film composed of a gluing resin layer 9 and an insulating layer 8 is provided as a base insulating film. The gluing resin layer 9 constitutes a lower layer of the base insulating film. The insulating layer 8 constitutes an upper layer of the base insulating film.

The gluing resin layer 9 is composed of a material having a breaking strength of 70 MPa or more at a temperature of 23° C. and having a breaking elongation percentage of 5% or more at a temperature of 23° C. The material for the gluing resin layer 9 may be applicable a strong resin that strongly resists heat and has a small dielectric constant. Such a resin includes, for example, an epoxy resin, a BT resin, cyanate resin, or thermoplastic polyimide. The epoxy resin may be, for example, ABF-GX (trade name) manufactured by Ajinomoto Fine-Techno Co., Inc. or APL-4501 (trade name) manufactured by SUMITOMO BAKELITE Co., Ltd. The cyanate resin may be, for example, LaZ (trade name) manufactured by SUMITOMO BAKELITE Co., Ltd. The thermoplastic polyimide may be, for example, TPI (trade name) manufactured by Mitsui Chemicals. Further, a resin having a particularly small dielectric constant and suffering a particularly small dielectric loss includes a polyolefin- or vinyl-based resin. These resins are more preferably used for substrates for high frequency transmissions.

The insulating layer 8 has a thickness of 1 μm or more, for example, 3 to 50 μm and has a breaking strength of 80 MPa or more, e.g. 100 MPa or more at a temperature of 23° C. When the insulating layer 8 is defined to have a breaking strength a at a temperature of −65° C. and a breaking strength b at a temperature of 150° C., the value of the ratio (a/b) is 2.5 or less. Further, when the insulating layer 8 is defined to have an elastic modulus c at a temperature of −65° C. and an elastic modulus d at a temperature of 150° C., the breaking strengths a and b and the elastic moduli c and d satisfy Formula 1. Further, the insulating layer 8 has an elastic modulus of 2.3 GPa or more at a temperature of 150° C. The insulating layer 8 is composed of a high-strength material that is stronger than the gluing resin layer 9. The insulating layer 8 is preferably a heat-resistant material which is not deformed at the setting temperature of the gluing resin layer 9 if the gluing resin layer 9 is formed of a thermosetting material and which is not softened or deformed at the softening temperature of the gluing resin layer 9 if the gluing resin layer 9 is formed of a thermoplastic material. Suitably, the insulating layer 8 is, for example, a polyimide film, an aramid film, or a liquid crystal film. The polyimide film is composed of aromatic polyimide or thermoplastic polyimide and may be, for example, KAPTON (trade name) manufactured by DU PONT-TORAY CO., LTD. or UPILEX (trade name) manufactured by UBE INDUSTRIES LTD. Further, the aramid film may be ARAMICA (trade name) manufactured by ASAHI CHEMICALS. The liquid crystal film may be, for example, Vexter (trade name) manufactured by KURARAY CO., LTD. or BIAC (trade name) manufactured by GORE-TEX.

The base insulating film as a whole composed of the insulating layer 8 and gluing resin layer 9 has a thickness of 3 to 100 μm, desirably 5 to 80 μm, more desirably 10 to 50 μm. The other arrangements and operations of the printed circuit board and semiconductor package of the present embodiment are similar to those in the previously described first embodiment. Description will be given below numerical scopes for the present invention.

Provided that the insulating layer has a film thickness of 1 μm or more, even if the gluing resin layer is cracked, the development of the crack can be stopped in the insulating layer. On the other hand, if the insulating layer has a film thickness of less than 1 μm, then the effect of stopping the development of the crack is insufficient. Therefore, the film thickness of the insulating layer should be 1 μm or more.

When the total thickness of the base insulating film exceeds 100 μm, the machinability of the via holes based on laser beam machining is markedly degraded. Accordingly, fine via holes cannot be formed. Therefore, the thickness of the base insulating film should be 100 μm or less.

In the present embodiment, the insulating layer 8 has a thickness of 1 μm or more and has a breaking strength of 80 MPa or more at a temperature of 23° C. Accordingly, even if the printed circuit board 13a is repeatedly thermally loaded to crack the gluing resin layer 9, the development of the crack can be stopped in the insulating layer 8. It is thus possible to prevent the occurrence of a crack that penetrates the base insulating film. This in turn prevents a possible crack penetrating the base insulating film from cutting the interconnects in the base insulating film or destroying the bumps connected to the base insulating film. When the insulating layer 8 is defined to have a breaking strength “a” at a temperature of −65° C. and a breaking strength “b” at a temperature of 150° C., the value of the ratio (a/b) is 2.5 or less. When the insulating layer 8 is defined to have an elastic modulus c at a temperature of −65° C. and an elastic modulus d at a temperature of 150° C., the breaking strengths “a” and “b” and the elastic moduli “c” and “d” satisfy Formula 1. The insulating layer 8 has an elastic modulus of 2.3 GPa or more at a temperature of 150° C. Then, strain stress that may occur in the base insulating film can be reduced to improve the reliability of the printed circuit board and the semiconductor package. The other effects of the present embodiment are similar to those of the previously described first embodiment.

In particular, if the insulating layer 8 is formed of polyimide, the development of a crack occurring in the gluing resin layer 9 can be stopped more effectively because the polyimide is stronger than the other general resins. Further, the polyimide is an insulating material having a smaller dielectric constant and suffering a smaller dielectric loss than an epoxy resin. Accordingly, this material serves to provide a printed circuit board suitable for use in a high frequency region. Furthermore, when the insulating layer 8 is formed of a liquid crystal polymer, since the liquid crystal polymer has an orientation of the order of molecules, the coefficient of thermal expansion can be controlled by controlling this orientation. As a result, the coefficient of thermal expansion of the insulating layer 8 can be set to be close to that of silicon or that of a metal interconnect consisting of copper or the like. By setting the coefficient of thermal expansion of the insulating layer 8 to be close to that of silicon, it is possible to reduce the difference in the coefficient of thermal expansion between the printed circuit board and the silicon substrate of the semiconductor device, to suppress thermal stress. Further, the liquid crystal polymer has a small dielectric constant, suffers a small dielectric loss, and has a small coefficient of water absorption. In this regard, the liquid crystal polymer can also be suitably used as an insulating material for an interconnect substrate.

The interface between the insulating layer 8 and the gluing resin layer 9 need not necessarily be definitely present. That is, the base insulating film may be an inclined material or the like having a composition continuously varying between the insulating layer 8 and the gluing resin layer 9.

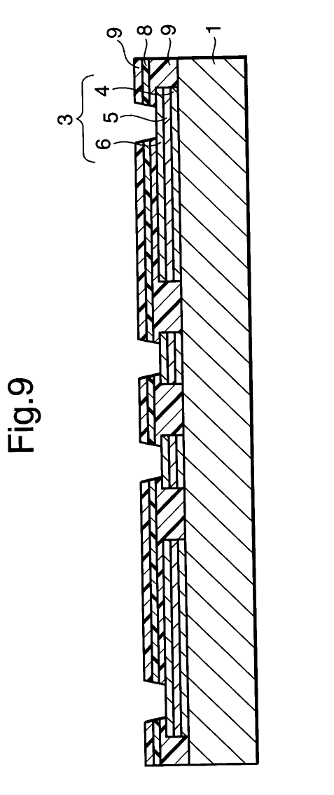

FIG. 9 is a sectional view showing a printed circuit board according to a variation of the present embodiment. As shown in FIG. 9, in the present variation, the base insulating film is a three-layer film composed of the gluing resin layer 9, the insulating layer 8, and the gluing resin layer 9. Specifically, the single insulating layer 8 is provided, and the two gluing resin layers 9 are provided so as to sandwich the insulating layer 8 between them. The other arrangements and manufacturing steps of the present variation are similar to those of the previously described second embodiment.

In the present variation, the adhesion between the base insulating film and the upper interconnects 11 can be improved compared to the previously described second embodiment. The other effects of the present variation are similar to those of the previously described first embodiment.

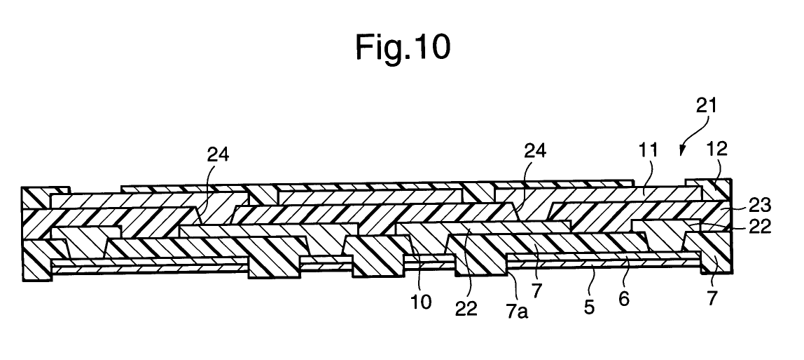

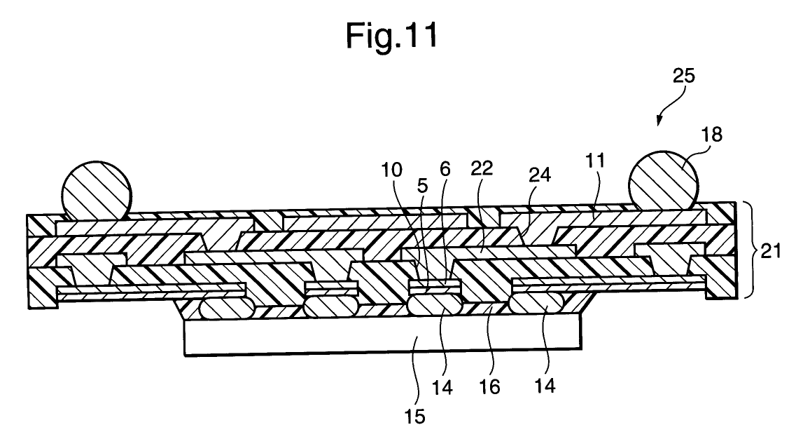

FIG. 10 is a sectional view showing a printed circuit board according to a third embodiment of the present invention. FIG. 11 is a sectional view showing a semiconductor package according to the present embodiment.

As shown in FIG. 10, the base insulating film 7 is provided in a printed circuit board 21 according to the present embodiment. The thickness and mechanical properties of the base insulating film 7 are similar to those of the base insulating film 7 in the first embodiment. The concave portions 7a are formed in the bottom surface of the base insulating film 7. The interconnect main body 6 is formed in each concave portion 7a. The etching barrier layer 5 is formed under the interconnect main body 6. The etching barrier layer 5 and the interconnect main body 6 constitute a lower interconnect. The lower interconnect is buried in the corresponding concave portion 7a. The arrangements of the etching barrier layer 5 and the interconnect main body 6 are similar to those in the previously described first embodiment.

Further, the via hole 10 is formed in a part of that area of the base insulating film 7 which is located immediately above each concave portion 7a. Furthermore, a conductive material is buried in each via hole 10. Intermediate interconnects 22 are formed on the base insulating film 7. The conductive material and intermediate interconnect 22 in each via hole 10 are integrally formed. The intermediate interconnect 22 is connected to the corresponding lower interconnect via the corresponding via hole 10. Furthermore, a final insulating film 23 is formed on the base insulating film 7 so as to cover the intermediate interconnects 22. Via holes 24 are each formed in a part of that area of the final insulating film 23 which is located immediately above the corresponding intermediate interconnect 22. A conductive material is buried in each via hole 24. The upper interconnects 11 are formed on the final insulating film 23. The conductive material and upper interconnect 11 in each via hole 24 are integrally formed. Each upper interconnect 11 is connected to the corresponding intermediate interconnect 22 via the corresponding via hole 24. Furthermore, the solder resists 12 are each formed on the final insulating film 23 so as to expose a part of the corresponding upper interconnect 11 while covering the remaining part. The exposed part of the upper interconnect 11 constitutes a pad electrode. The thickness and mechanical properties of the final insulating film 23 are similar to those of the base insulating film 7.

As shown in FIG. 11, in a semiconductor package 25 according to the present embodiment, the plurality of bumps 14 are connected to the etching barrier layer 5 in the previously described printed circuit board 21. The semiconductor device 15 is provided under the printed circuit board 21. Electrodes (not shown) of the semiconductor device 15 are connected to the respective bumps 14. Further, the underfill 16 is filled between the printed circuit board 21 and the semiconductor device 15 around each bump 14. On the other hand, the solder ball 18 is mounted on a part of the exposed portion, i.e. the pad electrode of each upper interconnect 11 in the printed circuit board 21. The solder ball 18 is connected to the corresponding electrode of the semiconductor device 15 via the upper interconnect 11, the via hole 24, the intermediate interconnect 22, the via hole 10, the lower interconnect composed of the interconnect main body 6 and etching barrier layer 5, and the bump 14. The other arrangements and operations of the printed circuit board and semiconductor package of the present embodiment are similar to those in the previously described first embodiment.

In the present embodiment, the printed circuit board 21 has a two-layer structure composed of the base insulating film 7 and the final insulating film 23. Accordingly, the present embodiment is more effective in relaxing the possible stress between the semiconductor device 15 and the solder balls 18 than the previously described first embodiment. Furthermore, since the printed circuit board 21 has a two-layer structure, it is possible to increase the number of signals inputted to and outputted from the semiconductor device 15. The other effects of the present embodiment are similar to those in the previously described first embodiment.

In the present embodiment, the base insulating film 7 may be composed as the gluing resin layer 9 and insulating layer 8 as in the case with the previously described second embodiment and its variation. In this case, the mechanical properties of the gluing resin layer 9 and insulating layer 8 are similar to those in the second embodiment.

Further, the following arrangements are possible. The base insulating film 7 is a single-layer insulating film having a configuration similar to that of the base insulating film in the previously described first embodiment. Specifically, the base insulating film 7 has a thickness of 3 to 100 μm and has a breaking strength of 80 MPa or more at a temperature of 23° C. When the base insulating film 7 is defined to have a breaking strength a at a temperature of −65° C. and a breaking strength b at a temperature of 150° C., the value of the ratio (a/b) is 2.5 or less. The final insulating film 23 has a configuration similar to that of the base insulating film in the previously described second embodiment, i.e. is composed of a gluing resin layer and an insulating layer. The mechanical properties of the gluing resin layer are such that its breaking strength is 70 MPa or more at a temperature of 23° C. and its breaking elongation percentage is 5% or more at a temperature of 23° C. The insulating layer has a thickness of 3 to 50 μm and has a breaking strength of 80 MPa or more at a temperature of 23° C. When the base insulating film 7 is defined to have a breaking strength a at a temperature of −65° C. and a breaking strength b at a temperature of 150° C., the value of the ratio (a/b) is 2.5 or less.

Furthermore, in the example of the present embodiment, the materials for the base insulating film 7 and final insulating film 23 are similar to that for the base insulating film in the first or second embodiment. However, in the present invention, fixed effects are obtained, provided that one of the materials for the base insulating film 7 and final insulating film 23 is similar to that for the base insulating film in the first or second embodiment.

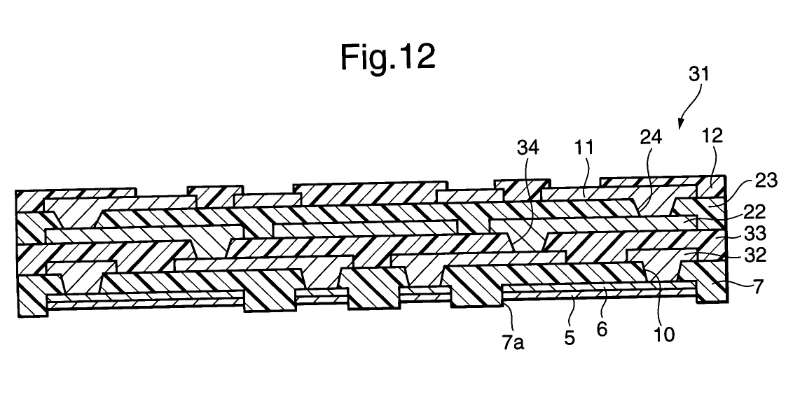

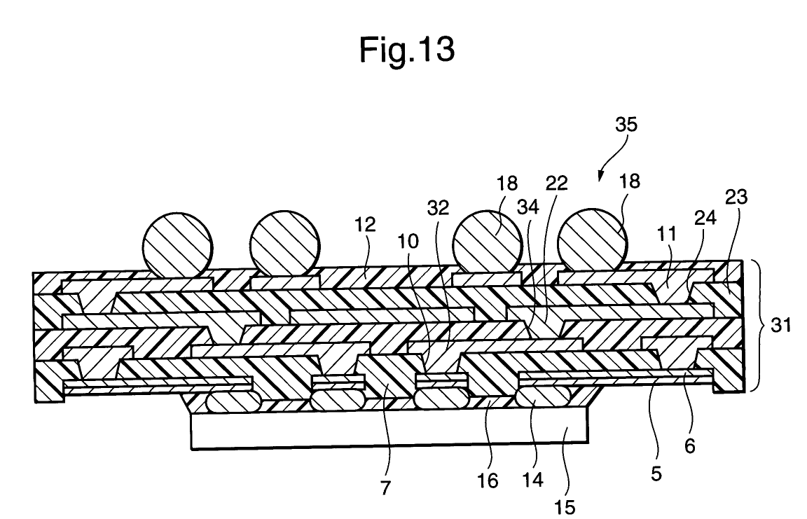

FIG. 12 is a sectional view showing a printed circuit board according to a fourth embodiment of the present invention. FIG. 13 is a sectional view showing a semiconductor package according to the present embodiment.

As shown in FIG. 12, the base insulating film 7 is provided in a printed circuit board 31 according to the present embodiment. The thickness and mechanical properties of the base insulating film 7 are similar to those of the base insulating film 7 in the first embodiment. The concave portions 7a are formed in the bottom surface of the base insulating film 7. The interconnect main body 6 is formed in each concave portion 7a. The etching barrier layer 5 is formed under the interconnect main body 6. The arrangements of the etching barrier layer 5 and the interconnect main body 6 are similar to those in the previously described first embodiment.

Further, the via hole 10 is formed in a part of that area of the base insulating film 7 which is located immediately above each concave portion 7a. Furthermore, a conductive material is buried in each via hole 10. Intermediate interconnects 32 are formed on the base insulating film 7. The conductive material and intermediate interconnect 32 in each via hole 10 are integrally formed. The intermediate interconnect 32 is connected to the corresponding lower interconnect via the corresponding via hole 10. Furthermore, an intermediate insulating film 33 is formed on the base insulating film 7 so as to cover the intermediate interconnects 32. Via holes 34 are each formed in a part of that area of the intermediate insulating film 33 which is located immediately above the corresponding intermediate interconnect 32. A conductive material is buried in each via hole 34. The intermediate interconnects 22 are formed on the intermediate insulating film 33. The conductive material and intermediate interconnect 22 in each via hole 34 are integrally formed. Each intermediate interconnect 22 is connected to the corresponding intermediate interconnect 32 via the corresponding via hole 34.

Furthermore, the final insulating film 23 is formed on the intermediate insulating film 33 so as to cover the intermediate interconnects 22. The via holes 24 are each formed in a part of that area of the final insulating film 23 which is located immediately above the corresponding intermediate interconnect 22. A conductive material is buried in each via hole 24. The upper interconnects 11 are formed on the final insulating film 23. The conductive material and upper interconnect 11 in each via hole 24 are integrally formed. Each upper interconnect 11 is connected to the corresponding intermediate interconnect 22 via the corresponding via hole 24. Moreover, the solder resists 12 are each formed on the final insulating film 23 so as to expose a part of the corresponding upper interconnect 11 while covering the remaining part. The exposed part of the upper interconnect 11 constitutes a pad electrode. The thickness and mechanical properties of the final insulating film 23 are similar to those of the base insulating film 7.

As shown in FIG. 13, in a semiconductor package 35 according to the present embodiment, the plurality of bumps 14 are connected to the etching barrier layer 5 in the previously described printed circuit board 31. The semiconductor device 15 is provided under the printed circuit board 31. Electrodes (not shown) of the semiconductor device 15 are connected to the respective bumps 14. Further, the underfill 16 is filled between the printed circuit board 31 and the semiconductor device 15 around each bump 14. On the other hand, the solder ball 18 is mounted on a part of the exposed portion, i.e. the pad electrode of each upper interconnect 11 in the printed circuit board 31. The solder ball 18 is connected to the corresponding electrode of the semiconductor device 15 via the upper interconnect 11, the via hole 24, the intermediate interconnect 22, the via hole 34, the intermediate interconnect 32, the via hole 10, the lower interconnect composed of the interconnect main body 6 and etching barrier layer 5, and the bump 14. The other arrangements and operations of the printed circuit board and semiconductor package of the present embodiment are similar to those in the previously described first embodiment.

In the present embodiment, the printed circuit board 31 has a three-layer structure composed of the base insulating film 7, the intermediate insulating film 33, and the final insulating film 23. Accordingly, the present embodiment is more effective in relaxing the possible stress between the semiconductor device 15 and the solder balls 18 than the previously described first and second embodiments. Furthermore, since the printed circuit board 31 has a three-layer structure, it is possible to increase the number of signals inputted to and outputted from the semiconductor device 15. The other effects of the present embodiment are similar to those in the previously described first embodiment.

In the present embodiment, the base insulating film 7 may be composed as the gluing resin layer 9 and insulating layer 8 as in the case with the previously described second embodiment and its variation. In this case, the mechanical properties of the gluing resin layer 9 and insulating layer 8 are similar to those in the second embodiment.

Further, the following arrangements are possible. The base insulating film 7 is a single-layer insulating film having a configuration similar to that of the base insulating film in the previously described first embodiment. Specifically, the base insulating film 7 has a thickness of 3 to 100 μm and has a breaking strength of 80 MPa or more at a temperature of 23° C. When the base insulating film 7 is defined to have a breaking strength a at a temperature of −65° C. and a breaking strength b at a temperature of 150° C., the value of the ratio (a/b) is 2.5 or less. The final insulating film 23 has a configuration similar to that of the base insulating film in the previously described second embodiment.

Furthermore, in the example of the present embodiment, the materials for the base insulating film 7 and final insulating film 23 are similar to that for the base insulating film in the first or second embodiment. However, the present invention is not limited to this aspect. For example, in addition to the base insulating film 7 and the final insulating film 23, the intermediate insulating film 33 may be composed of a material similar to that for the base insulating film in the previously described first or second embodiment. This provides a more reliable printed circuit board and a more reliable semiconductor package. Fixed effects are obtained with reduced costs, provided that one of the materials for the base insulating film 7 and final insulating film 23 is similar to that for the base insulating film in the first or second embodiment.

Moreover, the previously described third embodiment shows the printed circuit board provided with the two layers of insulating films. The present fourth embodiment shows the printed circuit board provided with the three layers of insulating films. However, the present invention is not limited to this aspect. The printed circuit board may be provided with four or more layers of insulating films.

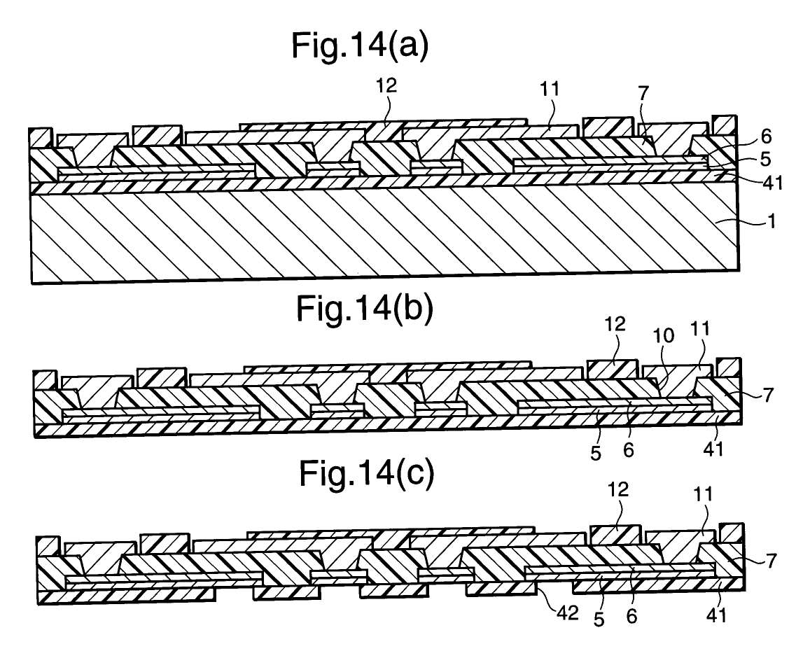

FIGS. 14(a) to 14(c) are sectional views showing a manufacturing method for and a configuration of a printed circuit board according to a fifth embodiment of the present invention. In the printed circuit board according to the present embodiment, the bottom surface of the base insulating film 7 is flush with the bottom surface of the lower interconnect composed of the etching barrier layer 5 and interconnect main body 6. Further, a protective film 41 is formed under the base insulating film 7. The protective film 41 is composed of, for example, an epoxy resin or polyimide and is, for example, 1 to 50 μm in thickness. Etching portions 42 are formed in the protective film 41 as openings. Each lower interconnect is partly exposed at the corresponding etching portion 42. That is, the protective film 41 exposes a part of the lower interconnect at the corresponding etching portion 42, while the other parts of the etching portion 42 cover the remaining part of the lower interconnect. In this regard, when the semiconductor device is mounted on this interconnect substrate, the bumps 14 are connected to the respective etching portions 42. The other arrangements and operations of the printed circuit board and semiconductor package of the present embodiment are similar to those in the previously described first embodiment.

In the present embodiment, the protective film 41 serves to improve the adhesion between the printed circuit board and the resin layer such as the underfill. The other effects of the present embodiment are similar to those of the first embodiment.

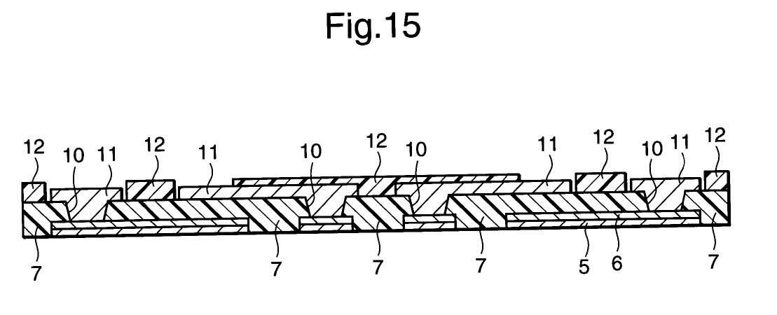

Now, a sixth embodiment of the present invention will be described. FIG. 15 is a sectional view showing a printed circuit board according to the present embodiment. As shown in FIG. 15, the printed circuit board according to the present embodiment is free from the protective film 41 compared to the printed circuit board according to the previously described fifth embodiment. Thus, the bottom surface of the lower interconnect is not concaved with respect to the bottom surface of the printed circuit board 43 but is flush with this bottom surface. The other arrangements of the printed circuit board of the present embodiment are similar to those in the previously described fifth embodiment.

The present embodiment is free from the protective film compared to the previously described fifth embodiment. Costs can be reduced. The other effects of the present embodiment are similar to those of the first embodiment.

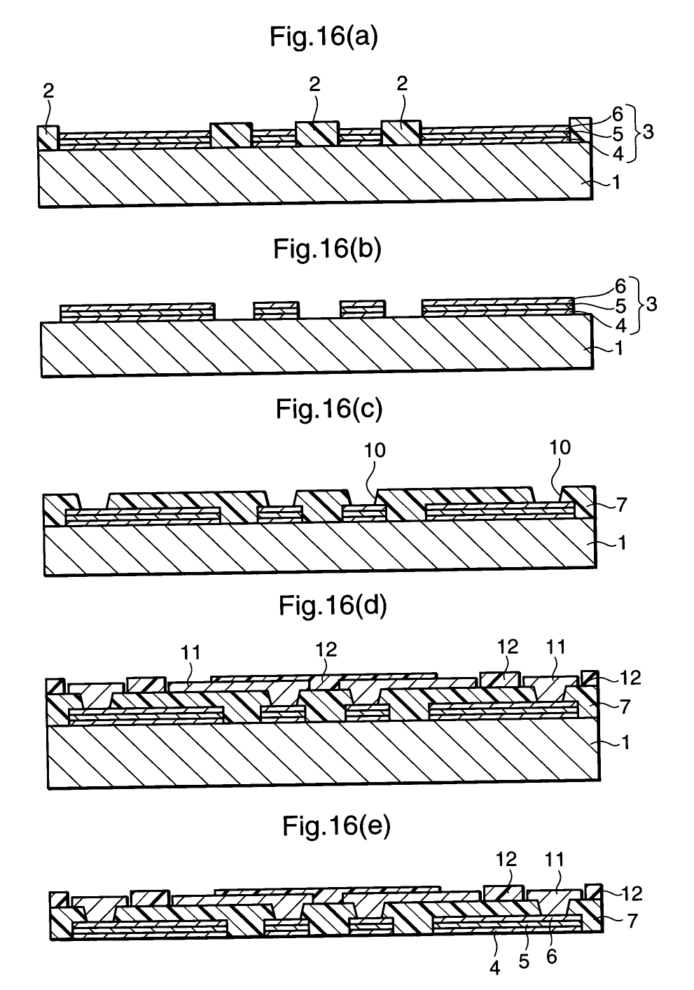

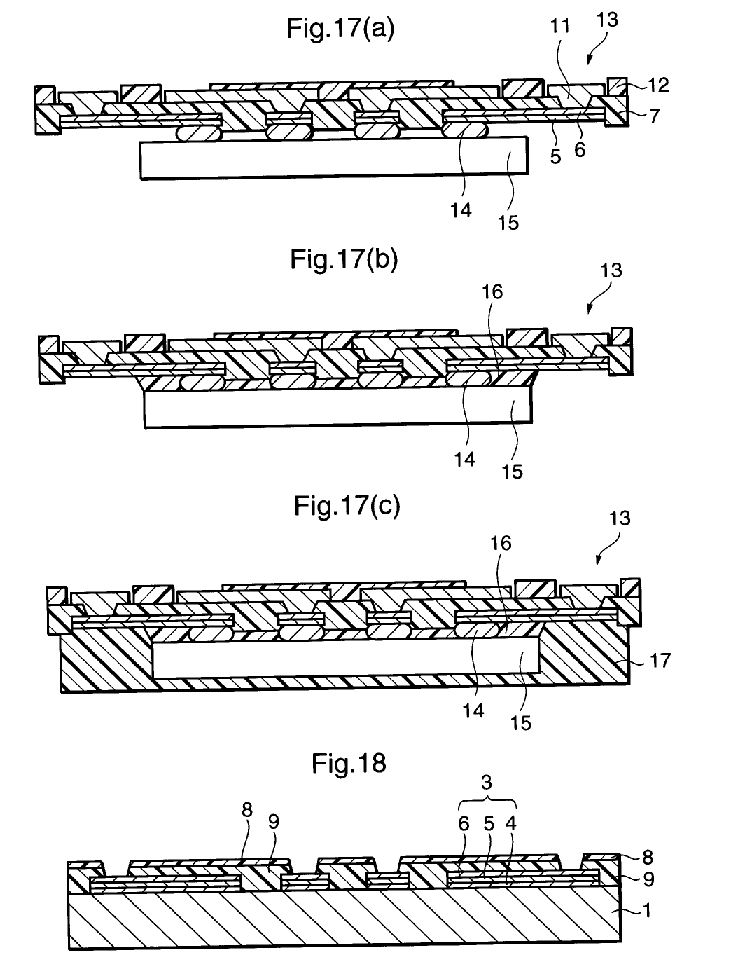

FIGS. 16(a) to 16(e) are sectional views showing a manufacturing method for the printed circuit board according to the first embodiment in order of the steps of the method. FIGS. 17(a) and 17(b) are sectional views showing a manufacturing method for the semiconductor package according to the present embodiment. First, as shown in FIG. 16(a), the support substrate 1 is provided which is composed of metal or alloy, e.g. Cu. A resist 2 is formed on the support substrate 1 and then patterned. Then, for example, a plating method is used to form the etching easy layer 4, etching barrier layer 5, and interconnect main body 6 in this order. In this case, a conductor interconnect layer 3 composed of the etching easy layer 4, etching barrier layer 5, and interconnect main body 6 is formed in those areas on the support substrate 1 from which the resist 2 has been removed. However, the conductor interconnect layer 3 is not formed in the areas in which the resist 2 remains. The etching easy layer 4 is formed of, for example, a single Cu plated layer, a two-layer plated layer composed of a Cu layer and an Ni layer, or a single Ni plated layer. The etching easy layer has a thickness of, for example, 0.5 to 10 μm. The Ni layer in the two-layer plated layer is provided in order to prevent the diffusion of the Cu layer in the etching easy layer 4 and the etching barrier layer 5 at high temperature. The Ni layer has a thickness of, for example, 0.1 μm or more. The etching barrier layer 5 is, for example, an Ni, Au, or Pd plated layer and has a thickness of, for example, 0.1 to 7.0 μm. The interconnect main body 6 is formed of, for example, a layer plated with a conductor such as Cu, Ni, Au, Al, and Pd. The interconnect main body 6 has a thickness of, for example, 2 to 20 μm. Even if the etching barrier layer 5 is formed of Au, an Ni layer may be formed between the etching barrier layer 5 and the interconnect main body 6 in order to prevent the diffusion of the etching barrier layer 5 and Cu, forming the interconnect main body 6.

Then, as shown in FIG. 16(b), the resist 2 is removed. Then, as shown in FIG. 16(c), the base insulating film 7 is formed so as to cover the conductor interconnect layer 3. The base insulating film 7 is formed by, for example, laminating a sheet-like insulating film on the support substrate 1 or using a press process to laminate the insulating film to the support substrate 1 and then executing a heating process of holding the resulting support substrate 1, for example, at a temperature of 100 to 400° C. for 10 minutes to 2 hours to set the insulating film. The temperature and time used for the heating process are properly adjusted depending on the type of the insulating film. This enables the formation of the base insulating film 7 composed of, for example, aramid. Alternatively, the base insulating film 7 is formed by applying a varnish-like insulating material on the support substrate 1 using a method such as a spin coat process, a curtain coat process, or a die coat process, drying the resulting support substrate 1 using an oven, a hot plate, or the like, and then executing a heating process of holding the support substrate 1, for example, at a temperature of 100 to 400° C. for 10 minutes to 2 hours to set the insulating material. This enables the formation of the base insulating film 7 composed of, for example, polyimide. Then, a laser beam machining process is used to form each via hole 10 in a part of that area of the base insulating film 7 which is located immediately above the conductor interconnect layer 3.

Then, as shown in FIG. 16(d), a conductive material is buried in each via hole 10, and the upper interconnects 11 are formed on the base insulating film 7. At this time, each upper interconnect 11 is connected to the interconnect main body 6 via the corresponding via hole 10. If the printed circuit board 13 is used for a semiconductor package composed of a CSP (Chip Sized Package), the via hole 10 is, for example, 40 μm in diameter. If the printed circuit board 13 is used for a semiconductor package composed of an FCB GA (Flip Chip Ball Grid Array), the via hole 10 is, for example, 75 μm in diameter. The conductive material buried in the via hole 10 as well as the upper interconnect 11 is each composed of a layer plated with a conductor such as Cu, Ni, Au, Al, or Pd and each has a thickness of, for example, 2 to 20 μm. Then, the solder resists 12 are each formed so as to expose a part of the corresponding upper interconnect 11 while exposing the remaining part. The solder resist 12 has a thickness of, for example, 5 to 40 μm. The formation of the solder resists 12 may be omitted.

Then, as shown in FIG. 16(e), the support substrate 1 is removed using chemical etching or polishing. Then, the etching easy layer 4 is etched and removed. In this case, if the material for the support substrate 1 is different from the material for the etching easy layer 4, an etching process must be executed twice as described above. However, if the support substrate 1 and the etching easy layer 4 are formed of the same material, an etching process may have only to be executed once.

Then, as shown in FIG. 17(a), the plurality of bumps 14 are joined to the respective exposed portions of the etching barrier layer 5. Then, the semiconductor device 15 is mounted on the printed circuit board 13 via the bumps 14 using a flip chip process. At this time, the electrodes (not shown) of the semiconductor device 15 are connected to the respective bumps 14.

Then, as shown in FIG. 17(b), the underfill 16 is poured into the space between the printed circuit board 13 and the semiconductor device 15 and is then solidified. This allows the bumps 14 to be buried in the underfill 16. In this regard, the formation of the underfill 16 may be omitted. Further, as shown in FIG. 17(c), a molding 17 may be formed on the bottom surface of the printed circuit board 13 so as to cover the underfill 16 and semiconductor device 15.

Then, the solder balls 18 are each mounted on the corresponding exposed portion of the upper interconnect 11 in the printed circuit board 13. Thus, the semiconductor package 19 according to the present embodiment is formed.

In the present embodiment, the conductor interconnect layer 3, the base insulating film 7, the upper interconnects 11, and others are formed on the hard support substrate 1, composed of, for example, Cu. Consequently, the flatness of the printed circuit board 13 can be improved.

In the example of the present embodiment, the support substrate 1 is composed of metal or alloy. However, the support substrate 1 may be composed of an insulator such as a silicon wafer, glass, ceramic, or a resin. If the substrate is made of an insulator, an electroless plating process may be used to form the conductor interconnect layer 3 after the resist 2 has been formed. Alternatively, after the resist 2 has been formed, the electroless plating process, a sputtering process, a vapor deposition process, or the like may be used to form a feeding conductor layer and then an electroplating process may be used to form the conductor interconnect layer 3.

Further, in the example of the present embodiment, the semiconductor device 15 is mounted on the printed circuit board 13 using the flip chip process. However, the semiconductor device 15 may be mounted on the printed circuit board 13 using another method such as a wire bonding process or a tape automated bonding process.

FIG. 18 is a sectional view showing a manufacturing method for the printed circuit board according to the second embodiment of the present invention. The method shown in FIGS. 16(a) and 16(b) is used to form the conductor interconnect layer 3 on the support substrate 1, the layer 3 being composed of the etching easy layer 4, the etching barrier layer 5, and the interconnect main body 6.

Subsequently, as shown in FIG. 18, the base insulating film composed of the gluing resin layer 9 and the insulating layer 8 is formed so as to cover the conductor interconnect layer 3 on the support substrate 1. At this time, the gluing resin layer 9 and the insulating layer 8 may be simultaneously stacked on the support substrate 1 to form the base insulating film. Alternatively, the gluing resin layer 9 and the insulating layer 8 may be laminated to each other to form the base insulating film before the base insulating film is stacked on the support substrate 1. Alternatively, the gluing resin layer 9 may be stacked on the support substrate 1 before insulating layer 8 is stacked on the gluing resin layer 9 to form the base insulating film. In these cases, if the gluing resin layer 9 is composed of a thermosetting resin, the gluing resin layer 9, composed of a thermosetting resin, is stacked on the insulating layer 8 or support substrate 1 by lamination or application so as to be half-set. After being stacked on the support substrate 1 or the insulating layer 8, the gluing resin layer 9, composed of a thermosetting resin, is held at a temperature of 100 to 400° C. for 10 minutes to several hours so as to be set. On the other hand, if the gluing resin layer 9 is composed of a thermoplastic resin, the gluing resin layer 9, composed of a thermoplastic resin, is heated and softened. The gluing resin layer 9 is then stacked on the insulating layer 8 or the support substrate 1. Such a method is used to form the base insulating film on the support substrate 1.

An insulating material for the insulating layer 8 has a breaking strength of 80 MPa or more at a temperature of 23° C. When this material is defined to have a breaking strength a at a temperature of −65° C. and a breaking strength b at a temperature of 150° C., the value of the ratio (a/b) is 2.5 or less. When this material is defined to have an elastic modulus c at a temperature of −65° C. and an elastic modulus d at a temperature of 150° C., the value of the ratio (c/d) is 4.7 or less. Further, the values of the items a to d satisfy Formula 1.

Then, laser beam machining is carried out to form the via holes 10 in the base insulating film composed of the gluing resin layer 9 and the insulating layer 8. The subsequent steps of the manufacturing method for the printed circuit board 13a are similar to the steps shown in FIGS. 16(d) and 16(e). Thus, the printed circuit board 13a according to the second embodiment is produced. Further, the semiconductor package manufacturing method according to the present embodiment is similar to the steps shown in FIGS. 17(a) and 17(b).

In the present embodiment, the provision of the gluing resin layer 9 in the base insulating film enables the support substrate 1 to adhere properly to the base insulating film. This allows a material that does not adhere tightly to the support substrate 1 to be used as a material for the insulating layer 8. In the present embodiment, the insulating layer 8 has the required mechanical properties, and the gluing resin layer 9 adheres tightly to the support substrate 1. This provides more choices for the material for the base insulating film. As a result, the performance of the base insulating film can be improved or its costs can be reduced. Such an insulating layer 8 is, for example, a liquid crystal polymer or polyimide.

Further, the conventional base insulating film is composed of an epoxy resin, but this resin is difficult to handle because it cannot be substantially elongated and is fragile. Thus, in general, the support substrate is composed of PET (PolyEthylene Terephthalate), and a film composed of an epoxy resin is formed on the support substrate. When this structure is used as a base insulating film, the support substrate is released from the epoxy resin film. Thus, when a printed circuit board is formed, it is necessary to have a step of releasing the support substrate from the epoxy resin film. Further, the base insulating film composed of an epoxy resin is likely to be cracked and cannot sufficiently tolerate thermal stress. In contrast, according to the method of the present embodiment, the insulating layer 8 composed of a high-strength material is also used as a support substrate for the epoxy film as the gluing resin layer 9. This eliminates the need for a step of releasing the support substrate. Further, the insulating layer 8 serves to prevent the development of a crack. A base insulating film is thus obtained which properly tolerates thermal stress.

Now, description will be given of a manufacturing method for the printed circuit board according to the variation of the second embodiment. In the present variation, the method shown in FIGS. 16(a) and 16(b) is used to form the conductor interconnect layer 3 on the support substrate 1. Subsequently, as shown in FIG. 9, the base insulating film composed of a three-layer film of the gluing resin layer 9, insulating layer 8, and gluing resin layer 9 is formed so as to cover the conductor interconnect layer 3. Other manufacturing methods according to the present variation are as described in the previously described second embodiment.

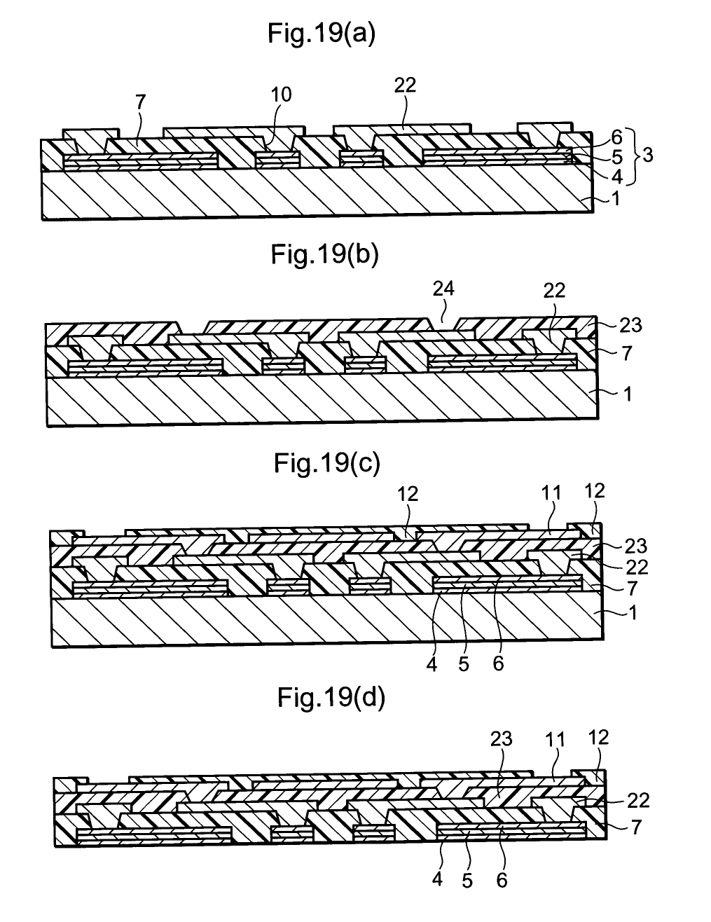

FIGS. 19(a) to 19(d) are sectional views showing a manufacturing method for the printed circuit board according to the third embodiment of the present invention. First, according to the method shown in FIGS. 19(a) to 19(c), the etching easy layer 4 and the conductor interconnect layer 3, composed of the etching barrier layer 5 and the interconnect main body 6, are formed on the support substrate 1. The base insulating film 7 is formed so as to cover the conductor interconnect layer 3. The via holes 10 are then formed in the base insulating film 7.

Then, as shown in FIG. 19(a), a conductive material is buried in each via hole 10. Then, the intermediate interconnects 22 are formed on the base insulating film 7. At this time, the intermediate interconnects 22 are connected to the interconnect main body 6 via the respective via holes 10. Then, as shown in FIG. 19(b), the final insulating film 23 is formed so as to cover the intermediate interconnects 22. The final insulating film 23 is formed similarly to, for example, the base insulating film 7. Then, the via holes 24 are each formed in a part of that area of the final insulating film 23 which is located immediately above the intermediate interconnect 22.

Then, as shown in FIG. 19(c), a conductive material is buried in each via hole 24. Further, the upper interconnects 11 are formed on the final insulating film 23. At this time, the upper interconnects 11 are connected to the corresponding intermediate interconnects 22 via the corresponding via holes 24. Then, the solder resists 12 are each formed so as to cover a part of the corresponding upper interconnect 11 while exposing the remaining part. Then, as shown in FIG. 19(d), the support substrate 1 is removed by chemical etching or polishing. Then, the etching easy layer 4 is etched and removed.

Then, as shown in FIG. 11, the plurality of bumps 14 are joined to the respective exposed portions of the etching barrier layer 5. Then, the semiconductor device 15 is mounted on the printed circuit board 21 via the bumps 14 using the flip chip process. At this time, the electrodes (not shown) of the semiconductor device 15 are connected to the respective bumps 14. Then, the underfill 16 is poured into the space between the printed circuit board 21 and the semiconductor device 15 and is then solidified. This allows the bumps 14 to be buried in the underfill 16. Then, the solder balls 18 are each mounted on the corresponding exposed portion of the upper interconnect 11 in the printed circuit board 21. Thus, the semiconductor package 25 according to the present embodiment, shown in FIG. 8, is formed. In this regard, the formation of the underfill 16 may be omitted as in the case with the previously described first and second embodiments. Alternatively, a molding may be formed on the bottom surface of the printed circuit board 21 so as to cover the underfill 16 and semiconductor device 15.

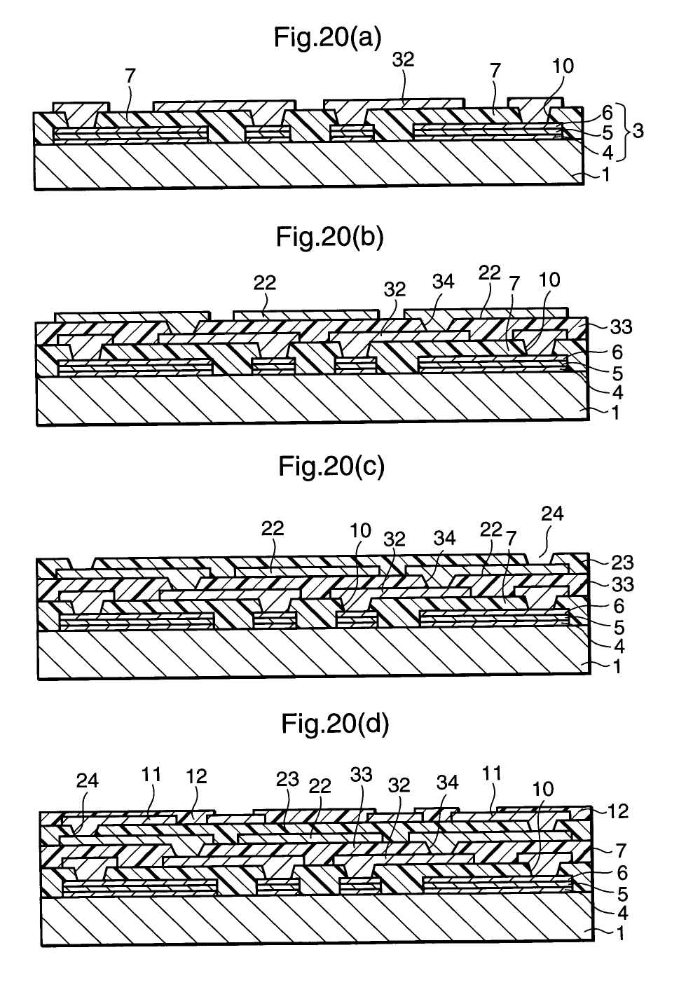

FIGS. 20(a) to 20(d) are sectional views showing a manufacturing method for the printed circuit board according to the fourth embodiment of the present invention. First, according to the method shown in FIGS. 16(a) to 16(c), the conductor interconnect layer 3 is formed on the support substrate 1. Then, the base insulating film 7 is formed so as to cover the conductor interconnect layer 3. The via holes 10 are then formed in the base insulating film 7.

Then, as shown in FIG. 20(a), a conductive material is buried in each via hole 10. Then, the intermediate interconnects 32 are formed on the base insulating film 7. At this time, the intermediate interconnects 32 are connected to the interconnect main body 6 via the respective via holes 10. Then, as shown in FIG. 20(b), the intermediate insulating film 33 is formed so as to cover the intermediate interconnects 32. Then, the via holes 34 are each formed in a part of that area of the intermediate insulating film 33 which is located immediately above the intermediate interconnect 32. Then, a conductive material is buried in each via hole 34. Further, the intermediate interconnects 22 are formed on the intermediate insulating film 33. The intermediate interconnects 22 are connected to the corresponding intermediate interconnects 32 via the corresponding via holes 34.

Then, as shown in FIG. 20(c), the final insulating film 23 is formed so as to cover the intermediate interconnects 22. Then, the via holes 24 are each formed in a part of that area of the final insulating film 23 which is located immediately above the intermediate interconnect 22.

Then, as shown in FIG. 20(d), a conductive material is buried in each via hole 24. Further, the upper interconnects 11 are formed on the final insulating film 23. At this time, the upper interconnects 11 are connected to the corresponding intermediate interconnects 22 via the corresponding via holes 24. Then, the solder resists 12 are each formed so as to cover a part of the corresponding upper interconnect 11 while exposing the remaining part.

Then, the support substrate 1 is removed by chemical etching or polishing. Then, the etching easy layer 4 is etched and removed.

Then, as shown in FIG. 13, the plurality of bumps 14 are joined to the respective exposed portions of the etching barrier layer 5. Then, the semiconductor device 15 is mounted on the printed circuit board 31 via the bumps 14 using the flip chip process. At this time, the electrodes (not shown) of the semiconductor device 15 are connected to the respective bumps 14. Then, the underfill 16 is poured into the space between the printed circuit board 31 and the semiconductor device 15 and is then solidified. This allows the bumps 14 to be buried in the underfill 16. Then, the solder balls 18 are each mounted on the corresponding exposed portion of the upper interconnect 11 in the printed circuit board 31. Thus, the semiconductor package 35 according to the present embodiment is formed.

Now, description will be given of a manufacturing method for the printed circuit board according to the fifth embodiment. First, as shown in FIG. 14(a), the protective film 41 is laminated to the entire surface of the support substrate 1 using, for example, the laminating or the press process. Then, a heating process is executed by holding the resulting support substrate 1, for example, at a temperature of 100 to 400° C. for 10 minutes to 2 hours, to set the protective film 41. The temperature and time used for the heating process are properly adjusted depending on the material for the protective film 41. The protective film 41 is, for example, 1 to 50 μm in thickness.

Then, a resist (not shown) is formed on the protective film 41 and patterned. A lower interconnect composed of the etching barrier layer 5 and the interconnect main body 6 is formed on those areas of the protective film 41 from which the resist has been removed. Then, the base insulating film 7 is formed so as to cover the lower interconnects. The via holes 10 are formed in the base insulating film 7. A conductive material is buried in each via hole 10. Further, the upper interconnects 11 are formed on the base insulating film 7. Then, the solder resists 12 are each formed so as to cover a part of the upper interconnect 11.

Then, as shown in FIG. 14(b), the support substrate 1 is removed. Then, as shown in FIG. 14(c), the protective film 41 is etched and selectively removed. Each lower interconnect is exposed at the corresponding etching portion 42, from which the protective film 41 has been removed. This results in the formation of the printed circuit board according to the present embodiment. Other manufacturing methods for the printed circuit board and the semiconductor package according to the present embodiment are as described in the previously described first embodiment.

### EXAMPLES

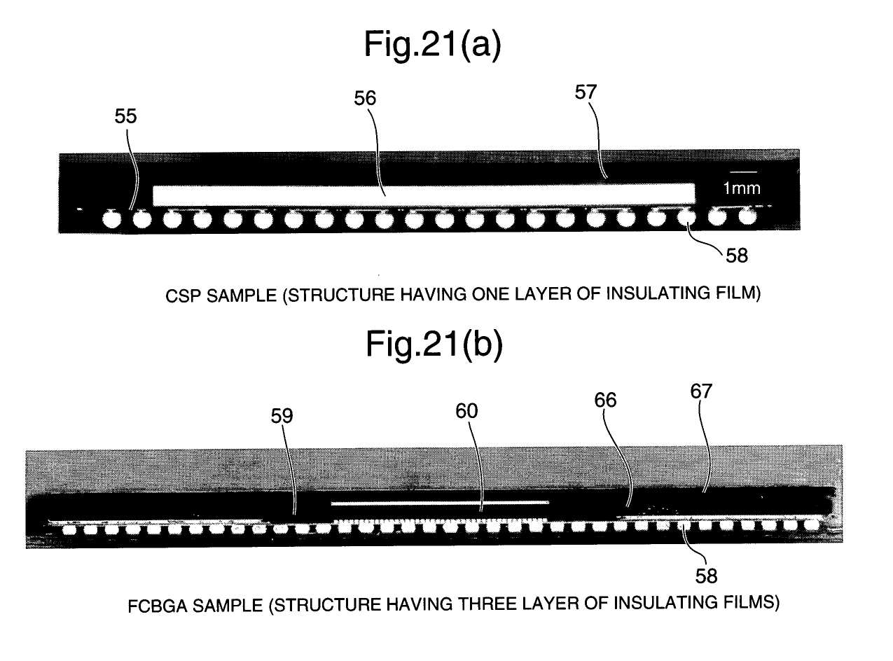

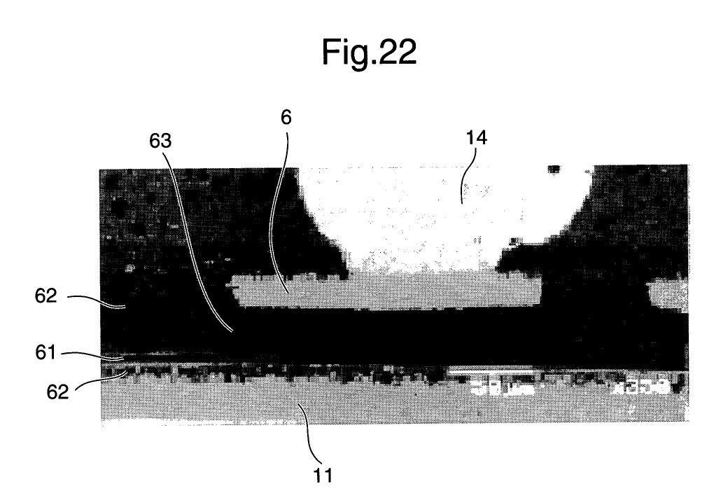

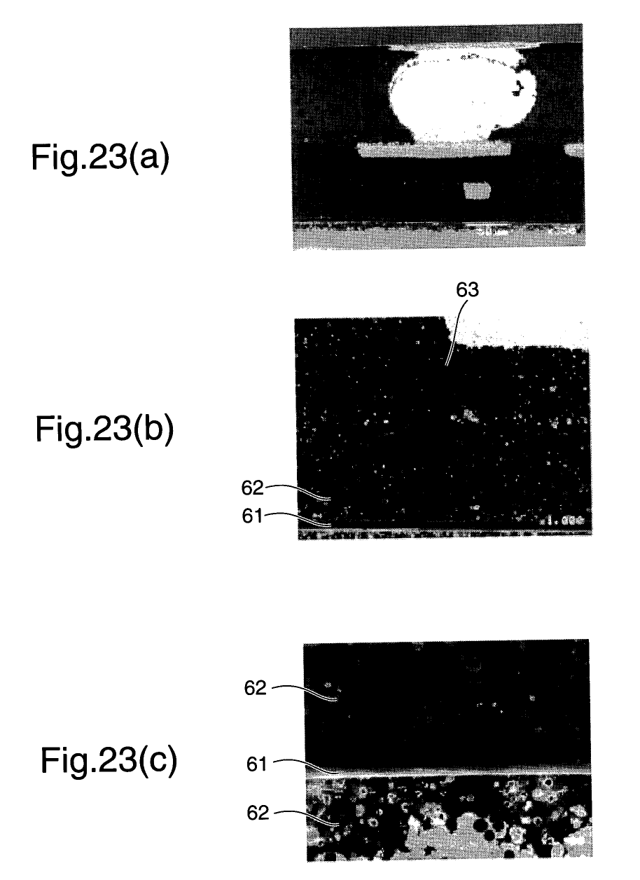

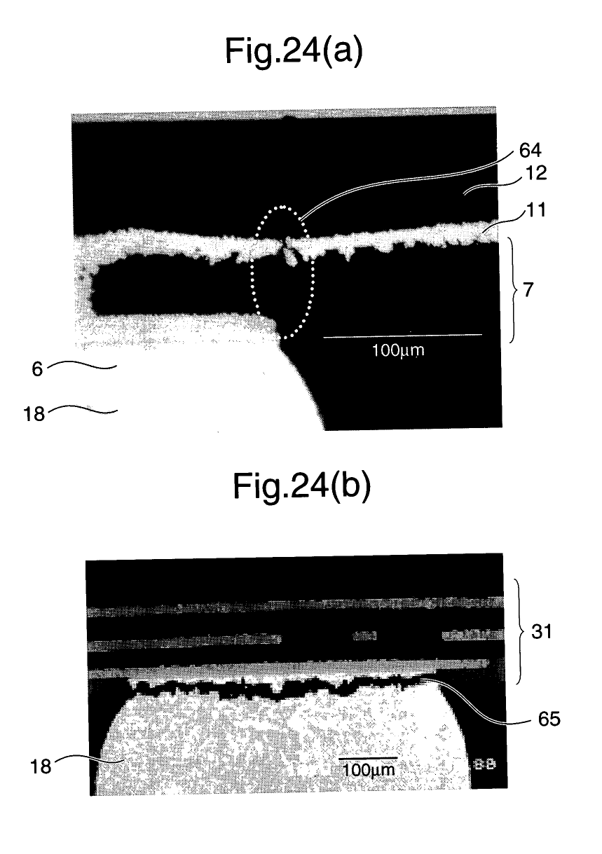

FIGS. 21(a) and 21(b) are microscopic photographs showing the shapes of samples for evaluative tests. FIG. 21(a) shows a CSP (Chip Sized Package) sample, and FIG. 21(b) shows an FCBGA (Flip Chip Ball Grid Array) sample. Further, FIGS. 22 and 23(a) to 23(c) are microscopic photographs showing an FCBGA sample according to Example No. 5 of the present invention, in which the development of a crack is stopped in an insulating layer. Furthermore, FIGS. 24(a) and 24(b) are microscopic photographs showing defective parts of open samples. FIG. 24(a) shows a crack in a resin. FIG. 24(b) shows a crack in a solder ball.

As shown in FIGS. 21(a) and 21(b), interconnect substrates each having one or three layers of insulating films were produced using the methods shown in the previously described first, second, and fourth embodiments. Then, an LSI as a semiconductor device and solder balls were mounted on each printed circuit board to produce two types of semiconductor packages, i.e. a CSP and FCBGA. A part of each semiconductor package was mounted on a mounting board to produce board mounted samples. The CSP semiconductor package unit or its board mounted sample will hereinafter be referred to as the “CSP sample”. The FCBGA semiconductor package unit or its board mounted sample will hereinafter be referred to as the “FCBGA sample”. The configurations of the CSP and FCBGA samples are shown in Table 1. For the interconnect substrates mounted in the CSP samples and each having one insulating layer, the type of resin constituting the base insulating film was varied among the samples. For the interconnect substrates mounted in the FCBGA samples and each having three insulating layers (base insulating film, intermediate insulating film, and final insulating film), the type of resin constituting the three insulating films was varied among the samples.

As shown in FIG. 21(a), in the CSP sample, an LSI 56 is mounted on a printed circuit board 55 and sealed by a molding 57. The printed circuit board 55 and the LSI 56 are connected together by wire bonding and are fixed to each other using a mount material (die attach material). Thus, no underfills are provided. Further, solder balls 58 are connected to the printed circuit board 55. The printed circuit board 55 has a single layer of an insulating film as in the case with the semiconductor package 19, shown in FIG. 5. A base insulating film is provided as the insulating film. Further, as shown in FIG. 21(b), in the FCBGA sample, an LSI 60 is mounted on a printed circuit board 59. An underfill is provided between the printed circuit board 59 and the LSI 60 and at the sides of the LSI 60. Stiffeners 66 are mounted on the printed circuit board 59 at the respective sides of the LSI 60. Further, a radiating sheet composed of heat conducting paste or the like is provided on the LSI 60. A heat spreader 67 formed of copper is provided on the radiating sheet and stiffeners 66. Furthermore, the solder balls 58 are connected to the printed circuit board 59. The printed circuit board 59 is provided with three insulating films, a base insulating film, an intermediate insulating film, and a final insulating film as in the case with the semiconductor package 35, shown in FIG. 13.

TABLE 1

| | CSP sample | FCBGA sample |
|---|---|---|
| LSI size | 9.0 × 9.0 mm | 10.5 × 10.5 mm |
| Package size | 12.0 × 12.0 mm | 37.5 × 37.5 mm |
| Number of insulating film | 1 | 3 |
| layers | | |
| Number of LSI pads | 384 | 2500 |
| Number of BGA balls | 384 | 1296 |

Then, for the samples shown in Table 1, the mechanical properties of the insulating film, i.e. its breaking strength, elastic modulus, and breaking elongation percentage, were measured. The measurement was carried out by cutting an insulating film in rectangles each of width 1 cm and conducting tensile tests in conformity with “JPCA Standard, Built-up Circuit Board, JPCA-BU01, Section 4.2”. A measurement temperature was set at three levels, −65° C., 23° C., and 150° C. The results of the measurements are shown in Table 2. For the types of resins for the insulating film shown in Table 2, reference character “P” denotes polyimide and reference character “A” denotes aramid. Reference characters “L”, “E”, and “F” denote a liquid crystal polymer, epoxy, and a porous fluorine resin. Further, reference character “+j” indicates that in addition to the insulating film, one or two gluing resin layers are provided.

Further, the dependence of the insulating film on temperature was calculated on the basis of the mechanical property values shown in Table 2. Specifically, the insulating film was defined to have a breaking strength “a” at a temperature of −65° C. and a breaking strength “b” at a temperature of 150° C., so that the ratio (a/b) was calculated. Further, the insulating film was defined to have an elastic modulus “c” at a temperature of −65° C. and an elastic modulus “d” at a temperature of 150° C., so that the ratio (c/d) was calculated. Furthermore, the value |c/d−a/b| was calculated. The results of these calculations are shown in Table 3.

Moreover, the thermal stress durability of the samples shown in Table 2 was evaluated. The evaluation of the thermal stress durability was executed on the semiconductor package unit and its board mounted sample. The unit CSP sample was subjected to a predetermined number of heat cycles each comprising holding the unit CSP sample at a temperature of −65° C. for 30 minutes and then holding it at a temperature of +150° C. for 30 minutes. The other samples, i.e. the board-mounted CSP sample, the unit FCBGA sample, and board-mounted FCBGA sample were subjected to a predetermined number of heat cycles each comprising holding each sample at a temperature of −40° C. for 30 minutes and then holding it at a temperature of +125° C. for 30 minutes. Then, each sample was evaluated for the number of cycles in which an open electric connection, i.e. an open circuit occurred. The times from the start of the low temperature (−65° C. or −40° C.) till the start of the high temperature (+150° C. or +125° C.) and from the start of the high temperature till the start of the low temperature were properly adjusted because they varied with the capabilities of a heat cycle tester and the thermal capacity of the sample.

When the thermal stress durability of semiconductor devices is evaluated, if heat cycle tests are conducted under actual use conditions (25 to 70° C.), the tests require a long time. Thus, accelerated tests are carried out by subjecting the samples to a heat cycle of −65 to 150° C. or −40 to 125° C. EIAJ-ET-7404 for temperature cycle test accelerating capabilities (established in April, 1999) shows values determined using the Coffin-Manson equation. These values indicate that for example, a heat cycle of −40 to 125° C. increases the speed of the tests by a factor of 5.7 compared to the actual use conditions (25 to 70° C. and one cycle/day). Thus, 600 cycles at −40 to 125° C. correspond to about 10 years under the actual use conditions.

Table 3 shows the results of the evaluation for the thermal stress durability tests. In Table 3, the term “resin crack” indicates that the resin of the insulating film was cracked. The term “solder crack” indicates that the solder ball was cracked. Further, the terms “more than 1,000” and “more than 500” indicate that the sample was not brought into an open state even after 1,000 and 500 heat cycles, respectively

TABLE 2

| | | | | | Mechanical properties | | | | | | | | |
|---|---|---|---|---|---|---|---|---|---|---|---|---|---|
| | | Insulating film | | | −65° C. | | | 23° C. | | | 150° C. | | |
| | | | | Film | Break- | Elastic | Breaking | | | Breaking | Break- | Elastic | Breaking |
| | | | | thick- | ing | mod- | elongation | Breaking | Elastic | elongation | ing | mod- | elonga-tion |
| | | Configur- | Resin | ness | strength | ulus | percen- | strength | modulus | percen- | strength | ulus | percen-tage |
| | No. | ration | type | (μm) | (Mpa) | (Gpa) | tage (%) | (Mpa) | (Gpa) | tage (%) | (Mpa) | (Gpa) | (%) |
| Example | 1 | Single layer | P | 30 | 415 | 5.1 | 44.0 | 410 | 5.0 | 49.0 | 333 | 2.8 | 60.0 |
| Example | 2 | Two layers | P | 30 | 415 | 5.1 | 44.0 | 410 | 5.0 | 49.0 | 333 | 2.8 | 60.0 |
| | | | +j | 20 | — | — | — | — | — | — | — | — | — |
| Example | 3 | Single layer | P | 50 | 310 | 3.8 | 122 | 270 | 3.7 | 131 | 205 | 2.3 | 170 |
| Example | 4 | Two layers | P | 25 | 314 | 3.9 | 120 | 274 | 3.8 | 129 | 205 | 2.3 | 165 |
| | | | +j | 40 | — | — | — | — | — | — | — | | |
| Example | 5 | Three layers | A | 4.5 | 400 | 15.0 | 18.0 | 390 | 14.1 | 19.5 | 283 | 9.1 | 25.0 |
| | | | +j | 10/30 | — | — | — | — | — | — | — | — | — |
| Example | 6 | Two layers | L | 25 | 169 | 9.4 | 19.0 | 112 | 6.3 | 25.0 | 70 | 3.1 | 28.0 |
| | | | +j | 40 | — | — | — | — | — | — | — | — | — |
| Example | 7 | Single layer | A | 60 | 276 | 10.4 | 3.6 | 255 | 6.7 | 4.3 | 180 | 4.8 | 4.3 |
| Example | 8 | Single layer | A | 60 | 197 | 8.5 | 3.1 | 177 | 6.2 | 3.8 | 115 | 4.0 | 3.8 |
| Example | 9 | Single layer | A | 60 | 165 | 6.7 | 3.0 | 151 | 4.9 | 3.6 | 85 | 3.2 | 3.6 |
| Example | 10 | Single layer | A | 60 | 155 | 6.4 | 2.8 | 143 | 4.4 | 3.2 | 62 | 2.8 | 3.2 |
| Example | 11 | Single layer | L | 50 | 180 | 11.0 | 33.0 | 135 | 9.0 | 42.0 | 110 | 4.5 | 50.0 |
| Example | 12 | Single layer | E | 60 | 142 | 4.3 | 7.4 | 80 | 3.3 | 11.0 | 35 | 1.1 | 36.0 |
| Example | 13 | Single layer | E | 60 | 152 | 4.1 | 5.5 | 89 | 3.1 | 11.0 | 34 | 0.87 | 37.0 |
| Comparative | 14 | Single layer | E | 60 | 143 | 6.0 | 2.9 | 122 | 4.6 | 4.1 | 29 | 0.60 | 22.0 |
| Example | | | | | | | | | | | | | |
| Comparative | 15 | Single layer | L | 60 | 158 | 9.4 | 4.9 | 89 | 3.9 | 7.1 | 30 | 1.5 | 5.4 |
| Example | | | | | | | | | | | | | |
| Comparative | 16 | Single layer | F | 60 | 131 | 4.6 | 8.8 | 54 | 2.6 | 8.8 | 18 | 0.34 | 55.0 |
| Example | | | | | | | | | | | | | |
| Comparative | 17 | Single layer | E | 60 | 123 | 3.9 | 8.4 | 76 | 2.2 | 7.8 | 25 | 0.66 | 18.4 |
| Example | | | | | | | | | | | | | |

TABLE 3

| | Dependence | | | | | | | | | | |
|---|---|---|---|---|---|---|---|---|---|---|---|
| | of mechanical | | | | | | | | | | |
| | properties | | | Thermal stress durability (number of defective cycles) | | | | | | | |
| | on temperature | | | CSP | | | | FCBGA | | | |
| | | | \|c/d- | Unit | | Board mounted | | Unit | | Board mounted | |
| | (a/b) | (c/d) | a/b\| | Resin | Solder | Resin | | | | | |
| No. | value | value | value | crack | crack | crack | Solder crack | Resin crack | Solder crack | Resin crack | Solder crack |

| | | | | | | | | | | | | |
|---|---|---|---|---|---|---|---|---|---|---|---|---|
| Example | 1 | 1.2 | 1.8 | 0.6 | More than | More than | More than | More than | More than | More than | More than | More than |
| | | | | | 1,000 | 1,000 | 500 | 500 | 1,000 | 1,000 | 500 | 500 |
| Example | 2 | 1.2 | 1.8 | 0.6 | More than | More than | More than | More than | More than | More than | More than | More than |
| | | — | — | — | 1,000 | 1,000 | 500 | 500 | 1,000 | 1,000 | 500 | 500 |
| Example | 3 | 1.5 | 1.7 | 0.1 | More than | More than | More than | More than | More than | More than | More than | More than |
| | | | | | 1,000 | 1,000 | 500 | 500 | 1,000 | 1,000 | 500 | 500 |
| Example | 4 | 1.5 | 1.7 | 0.2 | More than | More than | More than | More than | More than | More than | More than | More than |
| | | — | — | — | 1,000 | 1,000 | 500 | 500 | 1,000 | 1,000 | 500 | 500 |
| Example | 5 | 1.4 | 1.6 | 0.2 | More than | More than | More than | More than | More than | More than | More than | More than |
| | | — | — | — | 1,000 | 1,000 | 500 | 500 | 1,000 | 1,000 | 500 | 500 |
| Example | 6 | 2.4 | 3.0 | 0.6 | More than | More than | More than | More than | More than | More than | More than | More than |
| | | — | — | — | 1,000 | 1,000 | 500 | 500 | 1,000 | 1,000 | 500 | 500 |
| Example | 7 | 1.5 | 2.2 | 0.6 | More than | More than | More than | More than | More than | More than | More than | More than |
| | | | | | 1,000 | 1,000 | 500 | 500 | 1,000 | 1,000 | 500 | 500 |
| Example | 8 | 1.7 | 2.1 | 0.4 | More than | More than | More than | More than | More than | More than | More than | More than |
| | | | | | 1,000 | 1,000 | 500 | 500 | 1,000 | 1,000 | 500 | 500 |
| Example | 9 | 1.9 | 2.1 | 0.2 | More than | More than | More than | More than | More than | More than | More than | More than |
| | | | | | 1,000 | 1,000 | 500 | 500 | 1,000 | 1,000 | 500 | 500 |
| Example | 10 | 2.5 | 2.3 | 0.2 | More than | More than | More than | More than | More than | More than | More than | More than |
| | | | | | 1,000 | 1,000 | 500 | 500 | 1,000 | 1,000 | 500 | 500 |
| Example | 11 | 1.6 | 2.4 | 0.8 | More than | More than | More than | More than | More than | More than | More than | More than |
| | | | | | 1,000 | 1,000 | 500 | 500 | 1,000 | 1,000 | 500 | 500 |
| Example | 12 | 4.1 | 3.9 | 0.1 | 1000 | More than | More than | More than | More than | More than | More than | More than |
| | | | | | | 1,000 | 500 | 500 | 1,000 | 1,000 | 500 | 500 |
| Example | 13 | 4.5 | 4.7 | 0.2 | 1000 | More than | More than | More than | More than | More than | More than | More than |
| | | | | | | 1,000 | 500 | 500 | 1,000 | 1,000 | 500 | 500 |
| Com- | 14 | 4.9 | 10.0 | 5.1 | 100 | More than | 100 | More than | 100 | More than | 50 | More than |
| para- | | | | | | 1,000 | | 500 | | 1,000 | | 500 |
| tive | | | | | | | | | | | | |
| Example | | | | | | | | | | | | |
| Com- | 15 | 5.3 | 6.3 | 1.0 | 1000 | More than | More than | 400 | More than | More than | More than | 400 |
| para- | | | | | | 1,000 | 500 | | 1,000 | 1,000 | 500 | |
| tive | | | | | | | | | | | | |
| Example | | | | | | | | | | | | |
| Com- | 16 | 7.3 | 13.5 | 6.3 | 200 | More than | 300 | More than | 200 | More than | 200 | More than |
| para- | | | | | | 1,000 | | 500 | | 1,000 | | 500 |
| tive | | | | | | | | | | | | |
| Example | | | | | | | | | | | | |
| Com- | 17 | 4.9 | 5.9 | 1.0 | 500 | More than | 500 | 400 | 700 | More than | 400 | More than |
| para- | | | | | | 1,000 | | | | 1,000 | | 500 |
| tive | | | | | | | | | | | | |
| Example | | | | | | | | | | | | |

Nos. 1 to 13 shown in Tables 2 and 3 denote examples of the present invention. In Examples Nos. 1 to 13, when the insulating film was composed of a single layer (Examples Nos. 1, 3, and 7 to 13), it had a thickness of 3 to 100 μm and had a breaking strength of 80 MPa or more at a temperature of 23° C. Further, the value of the ratio (a/b) was 4.5 or less, and the value |c/d−a/b| was 0.8 or less. For the CSP samples, the open state resulting from a crack in the insulating film or solder ball was not observed until one thousand or more cycles had been applied. For the FCBGA samples, the open state was not observed even after 500 cycles had been applied. This indicates that these samples have an excellent thermal stress durability. Further, when the insulating film was composed of an insulating layer and a gluing resin layer (Examples Nos. 2, 4, 5, and 6), it had a thickness of 3 to 100 μm and the insulating layer had a breaking strength of 80 MPa or more at a temperature of 23° C. Further, the value of the ratio (a/b) was 4.5 or less, and the value |c/d−a/b| was 0.8 or less. For the CSP samples, the open state resulting from a crack in the insulating film or solder ball was not observed until one thousand or more cycles had been applied. For the FCBGA samples, the open state was not observed even after 500 cycles had been applied. This indicates that these samples have an excellent thermal stress durability.

In particular, in Examples No. 1 to 11, the value of the ratio (a/b) was 2.5 or less. Accordingly, the unit CSP samples were not brought into the open state even after 1,000 cycles had been applied. This indicates that these samples have an excellent thermal stress durability.

As shown in FIGS. 22 and 23(a) to 23(c), in the FCBGA sample according to Example No. 5, the insulating film was configured so that an aramid film 61 as an insulating layer was sandwiched between two layers of epoxy films 62 as gluing resin layers. After 1,000 heat cycles had been applied, a crack 63 occurred in the epoxy film 62 of the FCBGA sample owing to thermal stress. However, the development of the crack 63 was hindered by the aramid film 61. Accordingly, the entire insulating film was not broken. This prevented an open circuit and thus avoided bringing the printed circuit board into the open state.

In contrast, Nos. 14 to 17 shown in Tables 2 and 3 are comparative examples. In Comparative Examples No. 14 to 17, the value of the ratio (a/b) was larger than 4.5, and the value |c/d−a/b| was larger than 0.8. Accordingly, the mechanical properties of these samples depended markedly on the temperature. Consequently, these samples did not have a sufficient thermal stress durability.

As shown in FIG. 24(a), in the samples in Comparative Examples Nos. 14 to 17, in which the resin was cracked, a crack 64 occurred in the base insulating film 7. This crack 64 then open-circuited the upper interconnect 11. Thus, the printed circuit board 13 was brought into the open state. On the other hand, as shown in FIG. 24(b), in the samples in the Comparative Examples Nos. 14 to 17, in which the solder is cracked, a crack 65 occurred in the solder ball 18. This brought the printed circuit board 31 into the open state.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments without the use of inventive faculty. Therefore, the present invention is not intended to be limited to the embodiments described herein but is to be accorded the widest scope as defined by the limitations of the claims and equivalents.

What is claimed is:

1. A printed circuit board comprising:
a lower interconnect;
a base insulating film formed on said lower interconnect;
a via hole formed on said base insulating film;
an upper interconnect connected to said lower interconnect with said via hole, wherein said base insulating film has a thickness of about 3 to 100 μm and has a breaking strength of about 80 MPa or more at a temperature of 23° C., and
wherein, when said base insulating film is defined to have a breaking strength “a” at a temperature of −65° C. and a breaking strength “b” at a temperature of 150° C., a value of a ratio (a/b) is about 4.5 or less.

2. The printed circuit board according to claim 1, wherein when said base insulating film is defined to have an elastic modulus “c” at a temperature of −65° C. and an elastic modulus “d” at a temperature of 150° C., a value of a ratio (c/d) is about 4.7 or less.

3. The printed circuit board according to claim 1, wherein said value of said ratio (a/b) is about 2.5 or less.

4. The printed circuit board according to claim 1, wherein said value of said ratio (a/b) is larger than 2.5 and at most 4.5, and when said base insulating film is defined to have an elastic modulus “c” at a temperature of −65° C. and an elastic modulus “d” at a temperature of 150° C., said “a”, “b”, “c”, and “d” satisfy the following formula:
$$\vert \frac{c}{d} - \frac{a}{b} \vert \leq 0.8$$

5. The printed circuit board according to claim 1, wherein said base insulating film has an elastic modulus of about 2.3 GPa or more at a temperature of 150° C.

6. A printed circuit board comprising:
a lower interconnect;
a base insulating film formed on said lower interconnect;
a via hole formed on said base insulating film;
an upper interconnect connected to said lower interconnect with said via hole,
wherein said base insulating film comprises
a gluing resin layer, and
an insulating layer formed on said gluing resin layer, wherein said insulating layer has a thickness of about 1 μm or more, and a breaking strength of about 80 MPa or more at a temperature of 23° C., and when said insulating layer is defined to have a breaking strength “a” at a temperature of −65° C. and a breaking strength “b” at a temperature of 150° C., a value of a ratio (a/b) is about 2.5 or less.

7. The printed circuit board according to claim 6, wherein said base insulating film has another gluing resin layer formed on said insulating layer.

8. The printed circuit board according to claim 1,
further comprising at least one interconnect structure layer disposed between said base insulating film and said upper interconnect,
wherein said interconnect structure layer has an intermediate interconnect connected to said lower interconnect with said via hole, and at least one of a plurality of intermediate insulating films formed to cover said intermediate interconnect and having another via hole connecting said intermediate interconnect to said upper interconnect.

9. The printed circuit board according to claim 8, wherein at least one of said intermediate insulating films arranged in an uppermost layer has a breaking strength of about 80 MPa or more at a temperature of 23° C., and when said intermediate insulating film is defined to have a breaking strength “a1” at a temperature of −65° C. and a breaking strength “b1” at a temperature of 150° C., a value of a ratio (a1/b1) is about 4.5 or less.

10. The printed circuit board according to claim 8,
wherein all of said intermediate insulating films have a breaking strength of about 80 MPa or more at a temperature of 23° C., and when said intermediate insulating films are defined to have a breaking strength “a1” at a temperature of −65 ° C. and a breaking strength “b1” at a temperature of 150° C., a value of a ratio (a1/b1) is about 4.5 or less.

11. The printed circuit board according to claim 9,
wherein, when said intermediate insulating films are defined to have an elastic modulus “c1” at a temperature of −65° C. and an elastic modulus “d1” at a temperature of 150° C., a value of a ratio (c1/d1) is about 4.7 or less.

12. The printed circuit board according to claim 9,
wherein when said intermediate insulating films are defined to have an elastic modulus “c1” at a temperature of −65° C. and an elastic modulus “d1” at a temperature of 150° C., a value of a ratio (a1/b1) is about 2.5 or less.

13. The printed circuit board according to claim 9,
wherein when a value of a ratio (a1/b1) is larger than 2.5 and at most 4.5 and when intermediate insulating film is defined to have an elastic modulus “c1” at a temperature of −65° C. and an elastic modulus “d1” at a temperature of 150° C., said “a1”, “b1”, “c1” and “d1” satisfy the following formula:
$$\vert \frac{c1}{d1} - \frac{a1}{b1} \vert \leq 0.8$$

14. The printed circuit board according to claim 8,
wherein said intermediate insulating films have an elastic modulus of about 2.3 GPa or more at a temperature of 150° C.

15. The printed circuit board according to claim 1,
wherein said base insulating film has a concave portion in the bottom surface thereof and said lower interconnect is buried in said concave portion.

16. The printed circuit board according to claim 8,
wherein said base insulating film has a concave portion in the bottom surface thereof and said lower interconnect is buried in said concave portion.

17. The printed circuit board according to claim 15,
wherein a distance between a bottom surface of said lower interconnect and the bottom surface of said base insulating film is between 0.5 μm and 10 μm.

18. The printed circuit board according to claim 16,
wherein a distance between a bottom surface of said lower interconnect and the bottom surface of said base insulating film is between 0.5 μm and 10 μm.

19. The printed circuit board according to claim 1,
wherein a surface of said base insulating film and a surface of said lower interconnect are substantially flush with each other.

20. The printed circuit board according to claim 19,
further comprising a protective film formed on at least one part of said base insulating film and covering said lower interconnect.

21. The printed circuit board according to claim 1, further comprising a solder resist layer covering a part of said upper interconnect.

22. A semiconductor package comprising:
a printed circuit board according to claim 1; and
a semiconductor device mounted on said printed circuit board.

23. A base insulating film for a printed circuit board comprising;
a gluing resin layer, and
an insulating layer formed on said gluing resin layer, wherein said insulating layer has a thickness of about 1 μm or more, a breaking strength of about 80 MPa or more at a temperature of 23° C.,
wherein, when said insulating layer is defined to have a breaking strength “a” at a temperature of −65° C. and a breaking strength “b” at a temperature of 150° C., a value of a ratio (a/b) is about 2.5 or less, and
wherein said base insulating film has a thickness of about 3 to 100 μm.

24. The base insulating film according to claim 23, wherein said insulating layer has a breaking strength of about 100 MPa or more at a temperature of 23° C.

25. The base insulating film according to claim 23, wherein when said insulating layer has an elastic modulus “c” at a temperature of −65° C. and an elastic modulus “d” at a temperature of 150° C.,
wherein said “a”, “b”, “c”, and “d” satisfy the following formula:
$$\vert \frac{c}{d} - \frac{a}{b} \vert \leq 0.8$$

26. The base insulating film according to claim 23, said insulating layer has an elastic modulus of about 2.3 GPa or more at a temperature of 150° C.

27. The base insulating film according to claim 23, wherein said insulating layer is comprised of one or more types of resins selected from a group consisting of polyimide, aramid, a liquid crystal polymer, and any combination thereof.

28. A manufacturing method for a printed circuit board comprising:
providing a support substrate;
forming a lower interconnect on a support substrate;
forming a base insulating film having a thickness of 3 to 100 μm;
forming a via hole in a part of said base insulating film;
forming an upper interconnect on said base insulating film so that said upper interconnect is connected to said lower interconnect via said via hole; and
removing said support substrate,
wherein said step of forming said base insulating film includes a step of coating an insulating material on said support substrate, said insulating material having a breaking strength of about 80 MPa or more at a temperature of 23° C., and when said insulating material is defined to have a breaking strength “a” at a temperature of −65° C. and a breaking strength “b” at a temperature of 150° C., a value of a ratio (a/b) is about 4.5 or less.

29. The manufacturing method for a printed circuit board according to claim 28,
wherein, when said base insulating film is defined to have an elastic modulus “c” at a temperature of −65° C. and an elastic modulus “d” at a temperature of 150° C., a value of a ratio (c/d) is about 4.7 or less.

30. The manufacturing method for a printed circuit board according to claim 28,
wherein said value of a ratio (a/b) is about 2.5 or less.

31. The manufacturing method for a printed circuit board according to claim 28,
wherein said value of said ratio (a/b) is larger than 2.5 and at most 4.5, and when said base insulating film is defined to have an elastic modulus “c” at a temperature of −65° C. and an elastic modulus “d” at a temperature of 150° C., said “a”, “b”, “c” and “d” satisfy the following formula:
$$\vert \frac{c}{d} - \frac{a}{b} \vert \leq 0.8$$

32. The manufacturing method for a printed circuit board according to claim 28, wherein said base insulating film has an elastic modulus of about 2.3 GPa or more at a temperature of 150° C.

33. A manufacturing method for a printed circuit board comprising:
providing a support substrate;
forming a lower interconnect on a support substrate;
forming a base insulating film having a thickness of 3 to 100 μm;
forming a via hole in a part of a base insulating film;
forming an upper interconnect on said base insulating film so that said upper interconnect is connected to said lower interconnect via said via hole; and
removing said support substrate,
wherein said step of forming said base insulating film includes a step of forming a gluing resin layer and a step of forming an insulating layer of film thickness 1 μm or more on the gluing resin layer, and said step of forming said insulating layer has a step of coating an insulating material on said gluing resin layer, the insulating material having a breaking strength of about 80 MPa or more at a temperature of 23° C., and when said insulating material is defined to have a breaking strength “a” at a temperature of −65° C. and a breaking strength “b” at a temperature of 150° C., a value of a ratio (a/b) is about 2.5 or less.

34. The manufacturing method for a printed circuit board according to claim 33,
further comprising forming another gluing resin layer on said insulating layer.

35. The manufacturing method for a printed circuit board according to claim 28,
further comprising forming one or more interconnect structure layers after said forming said via hole and before said forming said upper interconnect,
wherein said forming one or more interconnect structure layers includes forming an intermediate interconnect to connect to said lower interconnect via said via hole, forming at least one of a plurality of intermediate insulating films to cover said intermediate interconnect, and forming a via hole in a part of said intermediate insulating film.

36. The manufacturing method for a printed circuit board according to claim 35,
wherein at least one of said intermediate insulating films arranged in an uppermost layer has a breaking strength of 80 MPa or more at a temperature of 23° C., and
wherein, when at least one of said intermediate insulating films arranged in an uppermost layer is defined to have a breaking strength “a1” at a temperature of −65° C. and a breaking strength “b1” at a temperature of 150° C., a value of a ratio (a1/b1) is about 4.5 or less.

37. The manufacturing method for a printed circuit board according to claim 35,
wherein all of said intermediate insulating films have an insulating film on said base insulating film or another intermediate insulating film located below said base insulating film, the insulating films having a breaking strength of about 80 MPa or more at a temperature of 23° C., and when said insulating film is defined to have a breaking strength “a” at a temperature of −65° C. and a breaking strength “b” at a temperature of 150° C., a value of a ratio (a/b) is about 4.5 or less.

38. The manufacturing method for a printed circuit board according to claim 36,
wherein when the intermediate insulating films are defined to have an elastic modulus “c1” at a temperature of −65° C. and an elastic modulus “d1” at a temperature of 150° C., a value of a ratio (c1/d1) is about 4.7 or less.

39. The manufacturing method for a printed circuit board according to claim 36,
wherein said value of said ratio (a1/b1) is about 2.5 or less.

40. The manufacturing method for a printed circuit board according to claim 36,
wherein when said intermediate insulating films for which the value of said ratio (a1/b1) is larger than 2.5 and at most 4.5 and said intermediate insulating films are defined to have an elastic modulus “c1” at a temperature of −65° C. and an elastic modulus “d1” at a temperature of 150° C., said “a1”, “b1”, “c1” and “d1” satisfy the following formula:
$$\vert \frac{c1}{d1} - \frac{a1}{b1} \vert \leq 0.8$$

41. The printed circuit board according to claim 36, wherein at least one of said intermediate insulating films has an elastic modulus of about 2.3 GPa or more at a temperature of 150° C.

42. The manufacturing method for a printed circuit board according to claim 28, further comprising:
forming an etching easy layer having film thickness 0.5 to 10 μm on said support substrate before said step of forming said lower interconnect on said support substrate, and
removing said etching easy layer after said removing said support substrate.

43. The manufacturing method for a printed circuit board according to claim 28, further comprising:
forming a protective layer before said forming said lower interconnect on said support substrate, and
removing said protective layer selectively to expose at least part of said lower interconnect after said step of removing said support substrate.

44. The manufacturing method for a printed circuit board according to claim 27, further comprising forming a solder resist layer covering a part of said upper interconnect after forming said upper interconnect.

45. The printed circuit board according to claim 1, wherein said value of a ratio (a/b) is about 0.22 or more.

46. The printed circuit board according to claim 1, wherein said value of a ratio (a/b) is about 1.0 or more.

47. The printed circuit board according to claim 2, wherein said value of a ratio (c/d) is about 0.21 or more.

48. The printed circuit board according to claim 2, wherein said value of a ratio (c/d) is about 1.0 or more.

49. The printed circuit board according to claim 9, wherein said value of a ratio (a1/b1) is about 0.22 or more.

50. The printed circuit board according to claim 9, wherein said value of a ratio (a1/b1) is about 1.0 or more.

51. The printed circuit board according to claim 11, wherein said value of a ratio (c1/d1) is about 0.21 or more.

52. The printed circuit board according to claim 11, wherein said value of a ratio (c1/d1) is about 1.0 or more.

53. The manufacturing method for a printed circuit board according to claim 28, wherein said value of a ratio (a/b) is about 0.22 or more.

54. The manufacturing method for a printed circuit board according to claim 28, wherein said value of a ratio (a/b) is about 1.0 or more.

55. The manufacturing method for a printed circuit board according to claim 29, wherein said value of a ratio (c/d) is about 0.21 or more.

56. The manufacturing method for a printed circuit board according to claim 29, wherein said value of a ratio (c/d) is about 1.0 or more.

57. The manufacturing method for a printed circuit board according to claim 36, wherein said value of a ratio (a1/b1) is about 0.22 or more.

58. The manufacturing method for a printed circuit board according to claim 36, wherein said value of a ratio (a1/b1) is about 1.0 or more.

59. The manufacturing method for a printed circuit board according to claim 38, wherein value of a ratio (c1/d1) is about 0.21 or more.

60. The manufacturing method for a printed circuit board according to claim 38, wherein value of a ratio (c1/d1) is about 1.0 or more.
